(19) United States
(12) Patent Application Publication
(10) Pub. No.: US 2022/0367827 A1
(43) Pub. Date: Nov. 17, 2022

(54) DISPLAY APPARATUS, MASK ASSEMBLY FOR MANUFACTURING THE SAME, AND APPARATUS FOR MANUFACTURING DISPLAY APPARATUS

(71) Applicant: Samsung Display Co., Ltd., Yongin-si (KR)

(72) Inventors: Sangshin Lee, Yongin-si (KR); Sanghoon Kim, Yongin-si (KR); Seoyeon Kim, Yongin-si (KR); Seil Kim, Yongin-si (KR); Youngeun Ryu, Yongin-si (KR); Jongsung Park, Yongin-si (KR); Sangmin Yi, Yongin-si (KR); Seungjin Lee, Yongin-si (KR); Wonyoung Jang, Yongin-si (KR)

(21) Appl. No.: 17/743,378

(22) Filed: May 12, 2022

(30) Foreign Application Priority Data
May 13, 2021 (KR) 10-2021-0062153

(51) Int. Cl. H01L 51/50; H01L 51/56; H01L 51/00

(52) U.S. Cl. CPC H01L 51/504; H01L 51/56; H01L 51/0011

(57) ABSTRACT

A display apparatus, a mask assembly for manufacturing the display apparatus, and an apparatus for manufacturing the display apparatus. The display apparatus includes a substrate, a first pixel electrode, a second pixel electrode, and a third pixel electrode located on the substrate and adjacent to one another, a first lower emission layer, a second lower emission layer, and a third lower emission layer respectively corresponding to the first through third pixel electrodes and configured to emit light of different wavelength bands, a counter electrode located on the first through third lower emission layers, and a first common layer located between the first through third pixel electrodes and the first through third lower emission layers. The first common layer includes a 1-1^{st} pattern unit, a 1-2^{nd} pattern unit, and a 1-3^{rd} pattern unit respectively corresponding to the first through third pixel electrodes and disconnected from one another.

### CROSS-REFERENCE TO RELATED APPLICATION

This application claims priority from and the benefit of Korean Patent Application No. 10-2021-0062153, filed on May 13, 2021, which is hereby incorporated by reference for all purposes as if fully set forth herein.

### BACKGROUND

### Field

Embodiments of the present invention relate generally to a display apparatus, a mask assembly for manufacturing the same, and an apparatus for manufacturing the display apparatus and, more specifically, to a display apparatus for improving display quality, a mask assembly for manufacturing the display apparatus, and an apparatus for manufacturing the display apparatus.

### Discussion of the Background

Display apparatuses provide visual information, such as images or videos, to users. As various electronic devices, such as computers or large TVs, have been developed, various types of display apparatuses applicable thereto have been developed. Recently, mobility-based electronic devices have been widely used. Recently, tablet personal computers (PCs), in addition to small electronic devices, such as mobile phones, have been widely used as mobile electronic devices. As the proportion of a display apparatus in an electronic device has gradually increased, the demand for a display apparatus having high quality, high efficiency, and long lifetime has increased.

Organic light-emitting display apparatuses among display apparatuses are widely used in various electronic devices due to their wide viewing angle, high contrast, and fast response time.

An organic light-emitting display apparatus includes an organic light-emitting diode that emits light through a pixel, and the organic light-emitting diode includes a pixel electrode, a counter electrode, and an intermediate layer located between the pixel electrode and the counter electrode and including an emission layer. In general, an organic light-emitting display apparatus controls whether each organic light-emitting diode emits light or a degree of light emission through a thin-film transistor electrically connected to each pixel electrode.

A display apparatus in the related art has a problem in that non-light-emitting pixels located around light-emitting pixels emit light together due to leakage current between adjacent organic light-emitting diodes, thereby reducing display quality.

The above information disclosed in this Background section is only for understanding of the background of the inventive concepts, and, therefore, it may contain information that does not constitute prior art.

### SUMMARY

One or more embodiments include a display apparatus for improving display quality by preventing undesirable light emission due to leakage current, a mask assembly for manufacturing the display apparatus, and an apparatus for manufacturing the display apparatus using the mask assembly. However, the embodiments are examples, and do not limit the scope of the inventive concepts.

Additional features will be set forth in part in the description which follows and, in part, will be apparent from the description, or may be learned by practice of the presented embodiments.

An embodiment of the present invention provides a display apparatus including a substrate, a first pixel electrode, a second pixel electrode, and a third pixel electrode located on the substrate and adjacent to one another, a first lower emission layer, a second lower emission layer, and a third lower emission layer respectively corresponding to the first through third pixel electrodes and configured to emit light of different wavelength bands, a counter electrode located on the first through third lower emission layers, and a first common layer located between the first through third pixel electrodes and the first through third lower emission layers, wherein the first common layer includes a 1-1^{st} pattern unit, a 1-2^{nd} pattern unit, and a 1-3^{rd} pattern unit respectively corresponding to the first through third pixel electrodes and disconnected from one another.

The display apparatus may further include a second common layer located between the first through third lower emission layers and the counter electrode, wherein the second common layer includes a 2-1^{st} pattern unit, a 2-2^{nd} pattern unit, and a 2-3^{rd} pattern unit respectively corresponding to the first through third pixel electrodes and disconnected from one another.

The display apparatus may further include a first upper emission layer located on the first lower emission layer to overlap the first lower emission layer and configured to emit light of a same wavelength band as that of the first lower emission layer, a second upper emission layer located on the second lower emission layer to overlap the second lower emission layer and configured to emit light of a same wavelength band as that of the second lower emission layer, and a third upper emission layer located on the third lower emission layer to overlap the third lower emission layer and configured to emit light of a same wavelength band as that of the third lower emission layer. The first through third upper emission layers are located under the counter electrode with the second common layer therebetween.

Thicknesses of the first through third upper emission layers may be different from one another, and thicknesses of the first through third lower emission layers may be different from one another.

The display apparatus may further include a charge generation layer located between the first through third lower emission layers and the first through third upper emission layers.

The charge generation layer may include an n-type charge generation layer and a p-type charge generation layer. At least one of the n-type charge generation layer and the p-type charge generation layer includes a first portion, a second portion, and a third portion respectively corresponding to the first through third lower emission layers and disconnected from one another.

The display apparatus may further include a third common layer located between the first through third lower emission layers and the charge generation layer. The third common layer includes a 3-1^{st} pattern unit, a 3-2^{nd} pattern unit, and a 3-3^{rd} pattern unit respectively corresponding to the first through third pixel electrodes and disconnected from one another.

The display apparatus may further include a fourth common layer located between the charge generation layer and the first through third upper emission layers. The fourth common layer includes a 4-1^{st} pattern unit, a 4-2^{nd} pattern unit, and a 4-3^{rd} pattern unit respectively corresponding to the first through third pixel electrodes and disconnected from one another.

Another embodiment of the present invention provides a display apparatus including a substrate, a first pixel electrode, a second pixel electrode, and a third pixel electrode located on the substrate and adjacent to one another, a first lower emission layer, a second lower emission layer, and a third lower emission layer respectively corresponding to the first through third pixel electrodes and configured to emit light of different wavelength bands, a first upper emission layer located on the first lower emission layer to overlap the first lower emission layer and configured to emit light of a same wavelength band as that of the first lower emission layer, a second upper emission layer located on the second lower emission layer to overlap the second lower emission layer and configured to emit light of a same wavelength band as that of the second lower emission layer, a third upper emission layer located on the third lower emission layer to overlap the third lower emission layer and configured to emit light of a same wavelength band as that of the third lower emission layer, a charge generation layer located between the first lower emission layer and the first upper emission layer, between the second lower emission layer and the second upper emission layer, and between the third lower emission layer and the third upper emission layer, and a counter electrode located on the first through third upper emission layers, wherein the charge generation layer includes a first portion, a second portion, and a third portion respectively corresponding to the first through third lower emission layers and disconnected from one another.

The display apparatus may further include a first common layer located between the first through third pixel electrodes and the first through third lower emission layers, wherein the first common layer includes a 1-1^{st} pattern unit, a 1-2^{nd} pattern unit, and a 1-3^{rd} pattern unit respectively corresponding to the first through third pixel electrodes and disconnected from one another.

The display apparatus may further include a second common layer located between the first through third lower emission layers and the counter electrode, wherein the second common layer includes a 2-1^{st} pattern unit, a 2-2^{nd} pattern unit, and a 2-3^{rd} pattern unit respectively corresponding to the first through third pixel electrodes and disconnected from one another.

The display apparatus may further include a third common layer located between the first through third lower emission layers and the charge generation layer, wherein the third common layer includes a 3-1^{st} pattern unit, a 3-2^{nd} pattern unit, and a 3-3^{rd} pattern unit respectively corresponding to the first through third pixel electrodes and disconnected from one another.

The display apparatus may further include a fourth common layer located between the charge generation layer and the first through third upper emission layers, wherein the fourth common layer includes a 4-1^{st} pattern unit, a 4-2^{nd} pattern unit, and a 4-3^{rd} pattern unit is respectively corresponding to the first through third pixel electrodes and disconnected from one another.

Thicknesses of the first through third upper emission layers may be different from one another, and thicknesses of the first through third lower emission layers may be different from one another.

Another embodiment of the present invention provides a mask assembly including a mask frame, and a mask sheet located on the mask frame and including a rib portion defining a plurality of opening portions. At least two of the plurality of opening portions of the mask sheet have different sizes in a plan view.

The rib portion of the mask sheet may define a first opening portion, a second opening portion, and a third opening portion having different sizes in a plan view.

Another embodiment of the invention provides an apparatus for manufacturing a display apparatus including a mask assembly aligned with a display substrate, and a deposition source located opposite to the display substrate with the mask assembly therebetween. The mask assembly includes a mask frame, and a mask sheet located on the mask frame and including a rib portion defining a plurality of opening portions, wherein at least two of the plurality of opening portions of the mask sheet have different sizes in a plan view.

The rib portion of the mask sheet may define a first opening portion, a second opening portion, and a third opening portion having different sizes in a plan view.

The display substrate may include a plurality of pixel electrodes that are spaced apart from one another, wherein the rib portion of the mask sheet is located between the plurality of pixel electrodes without overlapping the plurality of pixel electrodes in a plan view.

At least one of the plurality of opening portions of the mask sheet may overlap two pixel electrodes that are adjacent to each other and have a same size from among the plurality of pixel electrodes.

These general and specific embodiments may be implemented by using a system, a method, a computer program, or a combination thereof.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate illustrative embodiments of the invention, and together with the description serve to explain the inventive concepts.

FIG. 1 is a perspective view illustrating a display apparatus, according to an embodiment.

FIG. 2 is a cross-sectional view illustrating a display apparatus, according to an embodiment.

FIG. 3 is an equivalent circuit diagram illustrating a pixel circuit included in a display apparatus, according to an embodiment.

FIG. 4 is a plan view illustrating some elements of a display apparatus, according to an embodiment.

FIG. 5 is a cross-sectional view illustrating a part of a display apparatus, according to an embodiment.

FIG. 6 is a cross-sectional view illustrating a light-emitting device provided in a display apparatus, according to an embodiment.

FIG. 7 is a cross-sectional view illustrating a light-emitting device provided in a display apparatus, according to another embodiment.

FIG. 8 is a cross-sectional view illustrating a part of a display apparatus, according to another embodiment.

FIG. 9 is a cross-sectional view illustrating a light-emitting device provided in a display apparatus, according to another embodiment;

FIG. 10 is a cross-sectional view illustrating a light-emitting device provided in a display apparatus, according to another embodiment.

FIG. 11 is a cross-sectional view illustrating a light-emitting device provided in a display apparatus, according to another embodiment.

FIG. 12 is a cross-sectional view illustrating a light-emitting device provided in a display apparatus, according to another embodiment.

FIG. 13 is a cross-sectional view illustrating an apparatus for manufacturing a display apparatus, according to an embodiment.

FIG. 14 is a perspective view illustrating a mask assembly, according to an embodiment;

FIG. 15A is a plan view illustrating a part of a display substrate for manufacturing a display apparatus, according to an embodiment; and FIG. 15B is a plan view illustrating a part of a mask sheet aligned with the display substrate of FIG. 15A, according to an embodiment.

FIG. 16A is a plan view illustrating a part of a display substrate for manufacturing a display apparatus, according to another embodiment; and FIG. 16B is a plan view illustrating a part of a mask sheet aligned with the display substrate of FIG. 16A, according to another embodiment.

FIG. 17A is a plan view illustrating a part of a display substrate for manufacturing a display apparatus, according to another embodiment; and FIG. 17B is a plan view illustrating a part of a mask sheet aligned with the display substrate of FIG. 17A, according to another embodiment.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing illustrative features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

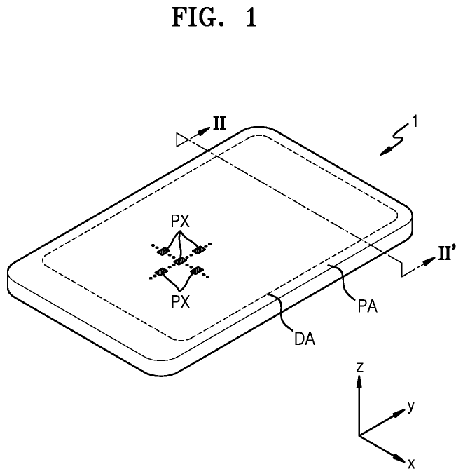

FIG. 1 is a perspective view illustrating a display apparatus, according to an embodiment.

Referring to FIG. 1, a display apparatus 1 may include a display area DA and a peripheral area PA located outside the display area DA. The display apparatus 1 may provide an image through an array of pixels PX in the display area DA. Each pixel PX may be defined as an emission area where a light-emitting device driven by a pixel circuit emits light. That is, an image may be provided by light emitted by the light-emitting device through the pixel PX. Not only light-emitting devices and pixel circuits, but also various signal wirings and power supply wirings electrically connected to the pixel circuits, may be located in the display area DA.

The peripheral area PA where an image is not provided may entirely or partially surround the display area DA. A driving circuit and various wirings for providing an electrical signal or power to the display area DA may be located in the peripheral area PA.

The display apparatus 1 may have a substantially rectangular shape when viewed in a direction perpendicular to a surface of the display apparatus 1. For example, as shown in FIG. 1, the display apparatus 1 may have a substantially rectangular planar shape having a short side extending in an x-direction and a long side extending in a y-direction. A corner where the short side in the x-direction and the long side in the y-direction meet each other may have a right-angled shape, or may have a round shape having a certain curvature as shown in FIG. 1. A planar shape of the display apparatus 1 is not limited to a rectangular shape, and may be any of various shapes such as a polygonal shape (e.g., a triangular shape), a circular shape, an elliptical shape, or an irregular shape.

Although the display apparatus 1 includes a flat display surface in FIG. 1, the inventive concepts are not limited thereto. In another embodiment, the display apparatus 1 may include a three-dimensional display surface or a curved display surface. When the display apparatus 1 includes a three-dimensional display surface, the display apparatus 1 may include a plurality of display areas indicating different directions, and may include, for example, a polygonal pillar-shaped display surface. In another embodiment, when the display apparatus 1 includes a curved display surface, the display apparatus 1 may be implemented as any of various types such as flexible, foldable, or rollable display apparatus.

Although the display apparatus 1 is used for a smartphone for convenience of explanation, the display apparatus 1 of the inventive concepts is not limited thereto. The display apparatus 1 may be used as a display screen of not only a portable electronic device such as a mobile phone, a smartphone, a tablet personal computer (PC), a mobile communication terminal, an electronic organizer, an electronic book, a portable multimedia player (PMP), a navigation device, or an ultra-mobile PC (UMPC) but also any of various products such as a television, a laptop computer, a monitor, an advertisement board, or an Internet of things (IoT) product. Also, the display apparatus 1 according to an embodiment may be used in a wearable device such as a smart watch, a watch phone, a glasses-type display, or a head-mounted display (HMD). Also, the display apparatus 1 according to an embodiment may be used as a center information display (CID) located on an instrument panel, a center fascia, or a dashboard of a vehicle, a room mirror display replacing a side-view mirror of a vehicle, or a display screen located on the back of a front seat for entertainment for a back seat of a vehicle.

Also, although the display apparatus 1 includes an organic light-emitting diode (OLED) as a light-emitting device, the display apparatus 1 of the inventive concepts is not limited thereto. In another embodiment, the display apparatus 1 may be a light-emitting display apparatus including an inorganic light-emitting diode, that is, an inorganic light-emitting display apparatus. In another embodiment, the display apparatus 1 may be a quantum dot light-emitting display apparatus.

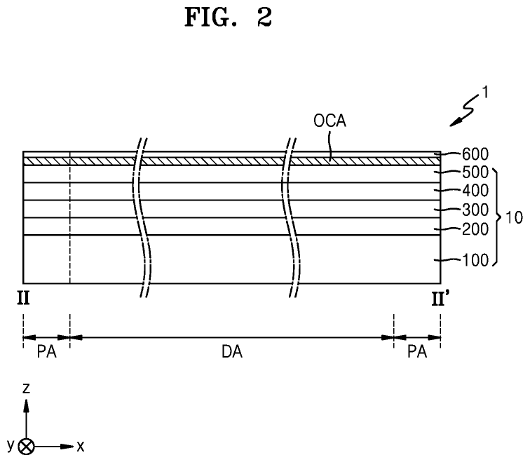

FIG. 2 is a cross-sectional view illustrating a display apparatus, according to an embodiment. FIG. 2 is a cross-sectional view taken along line II-II′ of the display apparatus 1 of FIG. 1.

Referring to FIG. 2, the display apparatus 1 may include a substrate 100, a display layer 200, a thin-film encapsulation layer 300, an input sensing layer 400, an anti-reflection layer 500, and a window layer 600. At least some of the display layer 200, the input sensing layer 400, the anti-reflection layer 500, and the window layer 600 located on the substrate 100 may be formed by using a continuous process, or at least some of the layers may be coupled to one another through an adhesive member. An optically clear adhesive (OCA) is illustrated as an adhesive member in FIG. 2. An adhesive member described below may include a general adhesive or a pressure-sensitive adhesive. In an embodiment, the anti-reflection layer 500 and the window layer 600 may be replaced with other elements or may be omitted.

The display layer 200 may include an OLED as a light-emitting element, and a pixel circuit electrically connected to the light-emitting element. The thin-film encapsulation layer 300 may be located on the display layer 200 to seal the organic light-emitting diode OLED. The thin-film encapsulation layer 300 may include at least one inorganic encapsulation layer and/or at least one organic encapsulation layer.

The display layer 200 may generate an image, and the input sensing layer 400 may obtain coordinate information of an external input (e.g., a touch event). Although not shown in FIG. 2, the display apparatus 1 according to an embodiment may further include a protective member located on a rear surface of the substrate 100. The protective member and the substrate 100 may be coupled to each other through an adhesive member.

In an embodiment, the input sensing layer 400 may be directly located on the thin-film encapsulation layer 300. When “an element B is directly located on an element A,” it means that an additional adhesive layer/adhesive member is not located between the element A and the element B. After the element A is formed, the element B is formed through a continuous process on a base surface provided by the element A. In another embodiment, the input sensing layer 400 may not be directly located on the thin-film encapsulation layer 300, but may be formed through a separate process and then may be located on the thin-film encapsulation layer 300 through the adhesive member.

The substrate 100, and a stacked structure of the display layer 200, the thin-film encapsulation layer 300, the input sensing layer 400, and the anti-reflection layer 500 located on the substrate 100 may be defined as a display panel 10.

The anti-reflection layer 500 may reduce a reflectance of external light incident from the top of the window layer 600. For example, the anti-reflection layer 500 may include a black matrix and a color filter, or may include a phase retarder and/or a polarizer. In an embodiment, an adhesive member may not be located between the input sensing layer 400 and the anti-reflection layer 500, and the anti-reflection layer 500 may be directly located on the input sensing layer 400.

Although the anti-reflection layer 500 is located on the input sensing layer 400 in FIG. 2, in another embodiment, the anti-reflection layer 500 may be located on the thin-film encapsulation layer 300 and the input sensing layer 400 may be located on the anti-reflection layer 500.

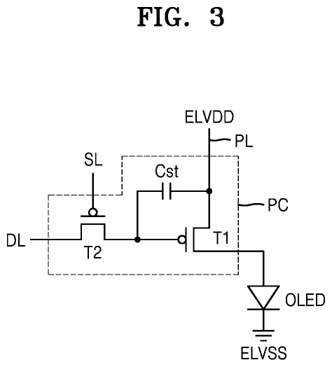

FIG. 3 is an equivalent circuit diagram illustrating a pixel circuit included in a display apparatus, according to an embodiment.

Referring to FIG. 3, a pixel circuit PC may include a plurality of thin-film transistors and a storage capacitor, and may be electrically connected to an organic light-emitting diode OLED. In an embodiment, the pixel circuit PC may include a driving thin-film transistor T1, a switching thin-film transistor T2, and a storage capacitor Cst.

The switching thin-film transistor T2 may be connected to a scan line SL and a data line DL, and may transmit a data signal or a data voltage input from the data line DL to the driving thin-film transistor T1 based on a scan signal or a switching voltage input from the scan line SL. The storage capacitor Cst may be connected to the switching thin-film transistor T2 and a driving voltage line PL, and may store a voltage corresponding to a difference between a voltage received from the switching thin-film transistor T2 and a first power supply voltage ELVDD supplied to the driving voltage line PL.

The driving thin-film transistor T1 may be connected to the driving voltage line PL and the storage capacitor Cst, and may control driving current flowing through the organic light-emitting diode OLED from the driving voltage line PL in response to a value of the voltage stored in the storage capacitor Cst. A counter electrode (e.g., a cathode) of the organic light-emitting diode OLED may receive a second power supply voltage ELVSS. The organic light-emitting diode OLED may emit light having a certain luminance according to the driving current.

Although the pixel circuit PC includes two thin-film transistors and one storage capacitor, the disclosure is not limited thereto. For example, the pixel circuit PC may include three or more thin-film transistors and/or two or more storage capacitors. In an embodiment, the pixel circuit PC may include seven thin-film transistors and one storage capacitor. The number of thin-film transistors and the number of storage capacitors may be changed in various ways according to a design of the pixel circuit PC. However, for convenience of explanation, the following will be described assuming that the pixel circuit PC includes two thin-film transistors and one storage capacitor.

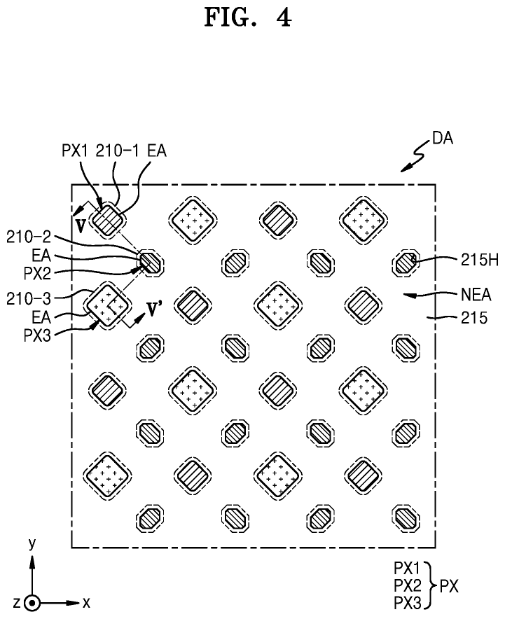

FIG. 4 is a plan view illustrating some elements of a display apparatus, especially in a display area of the display apparatus, according to an embodiment.

Referring to FIG. 4, a plurality of pixels PX may be located in the display area DA. Each pixel PX may be defined as an emission area EA where a light-emitting device, for example, an organic light-emitting diode, emits light. The pixel PX used herein may be a sub-pixel that emits red light, green light, blue light, or white light.

In an embodiment, the plurality of pixels PX may include a first pixel PX1, a second pixel PX2, and a third pixel PX3 that emit light of different colors. ‘Light of different colors’ may refer to light belonging to different wavelength bands. For example, the first pixel PX1, the second pixel PX2, and the third pixel PX3 may respectively emit red light, green light, and blue light, and the red light may be light belonging to a wavelength band of 580 nm to 780 nm, the green light may be light belonging to a wavelength band of 495 nm to 580 nm, and the blue light may be light belonging to a wavelength band of 400 nm to 495 nm.

A plurality of pixel electrodes 210 may be located in the display area DA, to be spaced apart from one another in a plan view. For example, a first pixel electrode 210-1, a second pixel electrode 210-2, and a third pixel electrode 210-3 that are spaced apart from one another may be located in the display area DA.

The pixel-defining film 215 may include a hole 215H through which a central portion of each of the plurality of pixel electrodes 210 is exposed. Although not shown in FIG. 4, emission layers emitting light may be respectively located in the holes 215H of the pixel-defining film 215, and a counter electrode may be located on the pixel-defining film 215 and the emission layers. The counter electrode may be integrally formed over the plurality of pixel electrodes 210.

A stacked structure of the pixel electrode 210, the emission layer, and the counter electrode may constitute one organic light-emitting diode. One hole 215H of the pixel-defining film 215 may correspond to one organic light-emitting diode and may define one emission area EA.

For example, an emission layer emitting red light may be located in the hole 215H through which a central portion of the first pixel electrode 210-1 is exposed, and the emission area EA defined by the hole 215H may constitute the first pixel PX1. Likewise, emission layers emitting green light and blue light may be respectively located in the holes 215H through which central portions of the second and third pixel electrodes 210-2 and 210-3 are exposed, and the emission areas EA defined by the holes 215H may respectively constitute the second pixel PX2 and the third pixel PX3.

A non-emission area NEA may be located between the plurality of pixels PX. The non-emission area NEA may be substantially an area between the emission areas EA. The counter electrode may be located in most of the non-emission areas NEA, and the pixel electrode 210 and the emission layer may not be located.

Although the plurality of pixels PX are arranged in an RGBG type (so-called Pentile® structure) in FIG. 4, the plurality of pixels PX may be arranged in any of various types, such as a stripe type.

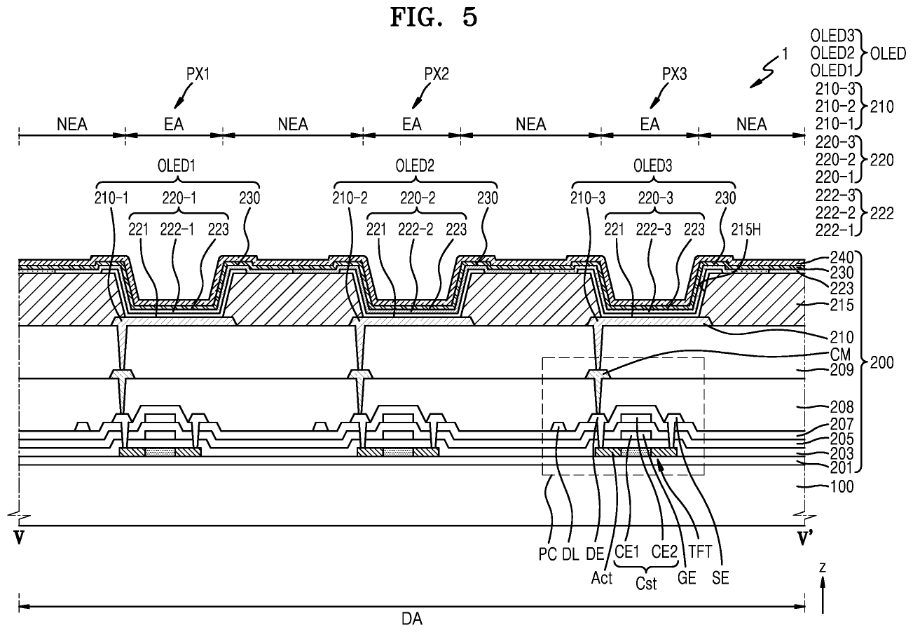

FIG. 5 is a cross-sectional view illustrating a part of a display apparatus, according to an embodiment. FIG. 5 is a cross-sectional view taken along line V-V of the display apparatus of FIG. 4.

Referring to FIG. 5, the display apparatus 1 may include the emission area EA and the non-emission area NEA, and each emission area EA may define any one of the first pixel PX1, the second pixel PX2, and the third pixel PX3. The organic light-emitting diode OLED may be located in the emission area EA, and the organic light-emitting diode OLED may be electrically connected to the pixel circuit PC to control light emission of the organic light-emitting diode OLED. A stacked structure of the organic light-emitting diode OLED and the pixel circuit PC will now be described.

First, the display apparatus 1 may include the substrate 100. The substrate 100 may include a glass material or a polymer resin. In an embodiment, the substrate 100 may include a plurality of sub-layers. The plurality of sub-layers may have a structure in which organic layers and inorganic layers are alternately stacked. When the substrate 100 includes a polymer resin, the substrate 100 may include polyethersulfone, polyacrylate, polyetherimide, polyethylene naphthalate, polyethylene terephthalate, polyphenylene sulfide, polyarylate, polyimide, polycarbonate, or cellulose acetate propionate.

The display layer 200 including a light-emitting element such as the organic light-emitting diode OLED and a thin-film encapsulation layer (not shown) covering the display layer 200 may be located on the substrate 100. The display layer 200 will now be described in detail.

A buffer layer 201 may be located on the substrate 100. The buffer layer 201 may be formed to prevent impurities from penetrating into a semiconductor layer Act of a thin-film transistor TFT. In an embodiment, the buffer layer 201 may include an inorganic insulating material, such as silicon nitride, silicon oxynitride, or silicon oxide, and may have a single or multi-layer structure including the above inorganic insulating material.

The pixel circuit PC may be located on the buffer layer 201. The pixel circuit PC may be located to correspond to each pixel PX. Because structures of the pixel circuits PC corresponding to the pixels PX are the same, one pixel circuit PC will be mainly described.

The pixel circuit PC includes a plurality of thin-film transistors TFT and the storage capacitor Cst. For convenience of explanation, one thin-film transistor TFT is illustrated in FIG. 5. For example, the thin-film transistor TFT may correspond to the driving thin-film transistor T1 (see FIG. 3). Although not shown in FIG. 5, the data line DL of the pixel circuit PC may be electrically connected to the switching thin-film transistor T2 (see FIG. 3) included in the pixel circuit PC.

The thin-film transistor TFT may include the semiconductor layer Act, a gate electrode GE, a source electrode SE, and a drain electrode DE.

The semiconductor layer Act may include polysilicon. Alternatively, the semiconductor layer Act may include amorphous silicon, an oxide semiconductor, or an organic semiconductor.

The gate electrode GE may include a low-resistance metal material. The gate electrode GE may include a conductive material including molybdenum (Mo), aluminum (Al), copper (Cu), or titanium (Ti), and may have a single or multi-layer structure including the above material.

A gate insulating layer 203 between the semiconductor layer Act and the gate electrode GE may include an inorganic insulating material, such as silicon oxide, silicon nitride, silicon oxynitride, aluminum oxide, titanium oxide, tantalum oxide, or hafnium oxide. The gate insulating layer 203 may have a single or multi-layer structure including the above material.

Although the thin-film transistor TFT is a top gate type transistor in which the gate electrode GE is located over the semiconductor layer Act with the gate insulating layer 203 therebetween in the present embodiment. In another embodiment, the thin-film transistor TFT may be a bottom gate type transistor.

The source electrode SE and the drain electrode DE may be located on the same layer as the data line DL, and may include the same material. The source electrode SE, the drain electrode DE, and the data line DL may include a material having high conductivity. Each of the source electrode SE and the drain electrode DE may include a conductive material, including molybdenum (Mo), aluminum (Al), copper (Cu), or titanium (Ti), and may have a single or multi-layer structure including the above material. In an embodiment, the source electrode SE, the drain electrode DE, and the data line DL may be formed to have a multi-layer structure including Ti/Al/Ti.

The storage capacitor Cst may include a lower electrode CE1 and an upper electrode CE2 overlapping each other with a first interlayer insulating layer 205 therebetween. The storage capacitor Cst may overlap the thin-film transistor TFT. In this regard, in FIG. 5, the gate electrode GE of the thin-film transistor TFT is the lower electrode CE1 of the storage capacitor Cst. In another embodiment, the storage capacitor Cst may not overlap the thin-film transistor TFT. The storage capacitor Cst may be covered by a second interlayer insulating layer 207. The upper electrode CE2 of the storage capacitor Cst may include a conductive material including molybdenum (Mo), aluminum (Al), copper (Cu), or titanium (Ti), and may have a single or multi-layer structure including the above material.

Each of the first interlayer insulating layer 205 and the second interlayer insulating layer 207 may include an inorganic insulating material, such as silicon oxide, silicon nitride, silicon oxynitride, aluminum oxide, titanium oxide, tantalum oxide, or hafnium oxide. Each of the first interlayer insulating layer 205 and the second interlayer insulating layer 207 may have a single or multi-layer structure including the above material.

The pixel circuit PC including the thin-film transistor TFT and the storage capacitor Cst may be covered by a first organic insulating layer 208. A top surface of the first organic insulating layer 208 may be substantially flat.

Although not shown in FIG. 5, a third interlayer insulating layer (not shown) may be further located under the first organic insulating layer 208. The third interlayer insulating layer may include an inorganic insulating material, such as silicon oxide, silicon nitride, or silicon oxynitride.

A second organic insulating layer 209 may be located on the first organic insulating layer 208. The second organic insulating layer 209 may provide a flat top surface for the organic light-emitting diode OLED located on the second organic insulating layer 209.

Each of the first organic insulating layer 208 and the second organic insulating layer 209 may include an organic insulating material such as a general-purpose polymer (e.g., polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof. In an embodiment, each of the first organic insulating layer 208 and the second organic insulating layer 209 may include polyimide.

A plurality of organic light-emitting diodes OLED may be located on the second organic insulating layer 209. For example, a first organic light-emitting diode OLED1, a second organic light-emitting diode OLED2, and a third organic light-emitting diode OLED3 that are adjacent to one another may be located on the second organic insulating layer 209. The first through third organic light-emitting diodes OLED1, OLED2, and OLED3 may emit light of different colors. For example, the first through third organic light-emitting diodes OLED1, OLED2, and OLED3 may respectively emit red light, green light, and blue light.

In an embodiment, the first organic light-emitting diode OLED1 may include a first pixel electrode 210-1, a first intermediate layer 220-1 including a first emission layer 222-1, and a counter electrode 230. The second organic light-emitting diode OLED2 may include a second pixel electrode 210-2, a second intermediate layer 220-2 including a second emission layer 222-2, and the counter electrode 230. The third organic light-emitting diode OLED3 may include a third pixel electrode 210-3, a third intermediate layer 220-3 including a third emission layer 222-3, and the counter electrode 230.

The organic light-emitting diode OLED may be electrically connected to the pixel circuit PC. For example, as shown in FIG. 5, the pixel electrode 210 of each organic light-emitting diode OLED may be electrically connected to the thin-film transistor TFT of the pixel circuit PC through a contact metal layer CM. The contact metal layer CM may be located between the thin-film transistor TFT and the pixel electrode 210. The contact metal layer CM may contact the thin-film transistor TFT through a contact hole formed in the first organic insulating layer 208, and the pixel electrode 210 may contact the contact metal layer CM through a contact hole formed in the second organic insulating layer 209 on the contact metal layer CM. The contact metal layer CM may include a conductive material including molybdenum (Mo), aluminum (Al), copper (Cu), or titanium (Ti), and may have a single or multi-layer structure including the above material. In an embodiment, the contact metal layer CM may have a multi-layer structure including Ti/Al/Ti.

A stacked structure of the first through third organic light-emitting diodes OLED1, OELD2, and OLED3 will now be described in detail.

The pixel electrodes 210, for example, the first pixel electrode 210-1, the second pixel electrode 210-2, and the third pixel electrode 210-3, may be located on the second organic insulating layer 209 on the substrate 100, and the first through third pixel electrodes 210-1, 210-2, and 210-3 may be adjacent to one another.

Each pixel electrode 210 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 210 may further include a film formed of ITO, IZO, ZnO, or In₂O₃ over and/or under the reflective film.

The pixel-defining film 215 may be formed on the pixel electrode 210. The pixel-defining film 215 may have the opening 215H through which a top surface of the pixel electrode 210 is exposed, and the pixel-defining film 215 may cover an edge of the pixel electrode 210. The pixel-defining film 215 may include an organic insulating material. Alternatively, the pixel-defining film 215 may include an inorganic insulating material, such as silicon nitride, silicon oxynitride, or silicon oxide. Alternatively, the pixel-defining film 215 may include an organic insulating material and an inorganic insulating material.

An emission layer 222 may be located on each pixel electrode 210. For example, the first emission layer 222-1, the second emission layer 222-2, and the third emission layer 222-3 may be respectively located on the first pixel electrode 210-1, the second pixel electrode 210-2, and the third pixel electrode 210-3. The first through third emission layers 222-1, 222-2, and 222-3 may respectively correspond to the first through third pixel electrodes 210-1, 210-2, and 210-3. When two elements “correspond to each other,” it may mean that the two elements overlap each other when viewed in a direction perpendicular to a surface of the substrate 100.

For example, adjacent emission layers 222 may contact each other in the non-emission area NEA. For example, the first emission layer 222-1 and the second emission layer 222-2 that are adjacent to each other may contact each other, and the second emission layer 222-2 and the third emission layer 222-3 that are adjacent to each other may contact each other. Although edges of the first emission layer 222-1 and the second emission layer 222-2 that are adjacent to each other contact each other and edges of the second emission layer 222-2 and the third emission layer 222-3 that are adjacent to each other contact each other, the inventive concepts are not limited thereto. When the emission layers 222 are formed, adjacent emission layers 222 may partially overlap or may be spaced apart from each other according to a process error. For example, the second emission layer 222-2 may partially overlap the first emission layer 222-1 that is adjacent to the second emission layer 222-2 on a side, and may be spaced apart from the third emission layer 222-3 that is adjacent to the second emission layer 222-2 on the other side. Each emission layer 222 may include a high molecular weight organic material or a low molecular weight organic material that emits light of a certain color. That is, the emission layer 222 may emit light of a certain wavelength band. In an embodiment, the first through third emission layers 222-1, 222-2, and 222-3 may emit light of different wavelength bands. For example, the first through third emission layers 222-1, 222-2, and 222-3 may respectively emit red light, green light, and blue light, and the red light may be light belonging to a wavelength band of 580 nm to 780 nm, the green light may be light belonging to a wavelength band of 495 nm to 580 nm, and the blue light may be light belonging to a wavelength band of 400 nm to 495 nm as described above. A first common layer 221 may be located under the emission layer 222. The first common layer 221 may be located between the pixel electrode 210 and the emission layer 222. For example, the first common layer 221 may be located between the first through third pixel electrodes 210-1, 210-2, and 210-3 and the first through third emission layers 222-1, 222-2, and 222-3.

The first common layer 221 may have a single or multi-layer structure. For example, when the first common layer 221 is formed of a high molecular weight material, the first common layer 221 that is a hole transport layer having a single-layer structure may be formed of poly-(3,4)-ethylene-dioxythiophene (PEDOT), polyaniline (PANT), N, N′-diphenyl-N,N′-bis(3-methylphenyl)-1,1′-bi-phenyl-4,4′-diamine (TPD), or N,N′-di(naphthalen-1-yl)-N,N′-diphenyl-benzidine (NPB). When the first common layer 221 is formed of a low molecular weight material, the first common layer 221 may include a hole injection layer (HIL) and a hole transport layer (HTL).

Also, a second common layer 223 may be located on the emission layer 222. The second common layer 223 may be located between the emission layer 222 and the counter electrode 230 described below. For example, the second common layer 223 may be located between the first through third emission layers 222-1, 222-2 and 222-3 and the counter electrode 230.

The second common layer 223 may not always be provided. For example, it is preferable that when each of the first common layer 221 and the second common layer 222-1 is formed of a high molecular weight material, the second common layer 223 is formed. The second common layer 223 may have a single or multi-layer structure. The second common layer 223 may include an electron transport layer (ETL) and/or an electron injection layer (EIL).

The first common layer 221, the emission layer 222, and the second common layer 223 may constitute an intermediate layer 220. For example, the first common layer 221, the first emission layer 222-1, and the second common layer 223 may constitute the first intermediate layer 220-1, the first common layer 221, the second emission layer 222-2, and the second common layer 223 may constitute the second intermediate layer 220-2, and the first common layer 221, the third emission layer 222-3, and the second common layer 223 may constitute the third intermediate layer 220-3.

The counter electrode 230 may be located on the first through third intermediate layers 220-1, 220-2, and 220-3. That is, the counter electrode 230 may be located on the first through third emission layers 222-1, 222-2, and 222-3. The counter electrode 230 may be formed of a conductive material having a low work function. For example, the counter electrode 230 may include a transparent (or semi-transparent) layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the counter electrode 230 may further include a layer formed of ITO, IZO, ZnO, or In₂O₃ on the transparent (or semi-transparent) layer including the above material.

The counter electrode 230 may be integrally formed over the plurality of pixel electrodes 210. For example, the counter electrode 230 may be located to overlap all of the first through third pixel electrodes 210-1, 210-2, and 210-3. The counter electrode 230 may be formed not only in the display area DA but also in the peripheral area PA (see FIG. 1).

In some embodiments, a capping layer 240 may be located on the counter electrode 230. For example, the capping layer 240 may have a single or multi-layer structure including a material selected from among an organic material, an inorganic material, and a mixture thereof. An LiF layer may be located on the capping layer 240 in an optional embodiment.

As a comparative example, when both the first common layer 221 and the second common layer 223 are integrally formed over the plurality of pixel electrodes 210, leakage current may flow between adjacent organic light-emitting diodes OLED through the first common layer 221 and the second common layer 223, thereby reducing display quality. For example, when it is desired that the second pixel PX2 emits green light and the first pixel PX1 and the third pixel PX3 do not emit red light and blue light, the pixel circuit PC may be controlled to apply driving current only to the second organic light-emitting diode OLED2. However, part of the driving current applied to the second organic light-emitting diode OLED2 may flow toward the first organic light-emitting diode OLED1 and/or the third organic light-emitting diode OLED3 adjacent to the second organic light-emitting diode OLED2 through the first common layer 221 and/or the second common layer 223. As a result, not only green light may be emitted from the second organic light-emitting diode OELD2, but also red light and/or blue light may be emitted from the first organic light-emitting diode OLED1 and/or the third organic light-emitting diode OLED3, thereby reducing color purity and display quality.

Because an interval between adjacent organic light-emitting diodes OLED decreases as a resolution of the display apparatus 1 increases, this risk may further increase. Also, when the first common layer 221 and/or the second common layer 223 includes a material having higher electrical conductivity in order to improve the lifetime and efficiency of the organic light-emitting diode OLED, this risk may further increase. Also, due to leakage current, there may be restrictions on a doping concentration and a thickness of the first common layer 221 and/or the second common layer 223. Accordingly, there may be limitations in improving the resolution, lifetime, and efficiency of the display apparatus 1.

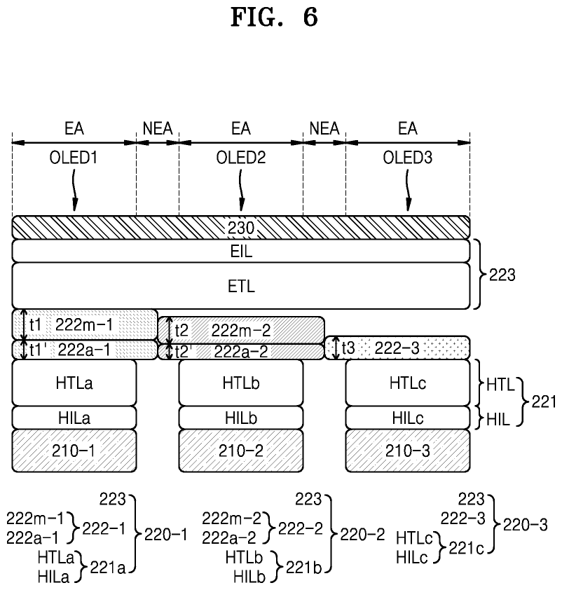

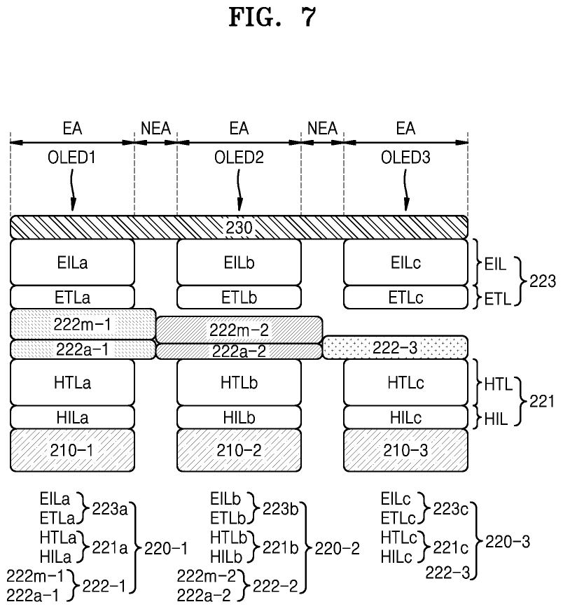

In order to solve the problems and limitations, according to an embodiment, at least one of the first common layer 221 and the second common layer 223 may not be integrally formed over the plurality of pixel electrodes 210, but instead may be patterned for each organic light-emitting diode OLED, which will be described with reference to FIGS. 6 and 7.

FIG. 6 is a cross-sectional view illustrating a light-emitting device provided in a display apparatus, according to an embodiment. FIG. 6 may correspond to a light-emitting device provided in the display apparatus of FIG. 5.

Referring to FIG. 6, the display apparatus 1 according to an embodiment may include an organic light-emitting diode as a light-emitting device. For example, the display apparatus 1 may include the first through third organic light-emitting diodes OLED1, OLED2, and OLED3 emitting light of different wavelength bands.

The first through third pixel electrodes 210-1, 210-2, and 210-3 respectively provided in the first through third organic light-emitting diodes OLED1, OLED2, and OLED3 may each be patterned for each emission area EA. That is, the first through third pixel electrodes 210-1, 210-2, and 210-3 may be spaced apart from one another, and may have island shapes (or isolated shapes) in a plan view.

The counter electrode 230 of the first through third organic light-emitting diodes OLED1, OLED2, and OLED3 may be integrally provided over the first through third organic light-emitting diodes OLED1, OLED2, and OLED3.

The first through third organic light-emitting diodes OLED1, OLED2, and OLED3 may respectively include the first through third emission layers 222-1, 222-2, and 222-3 located between the first through third pixel electrodes 210-1, 210-2, and 210-3 and the counter electrode 230. The first through third emission layers 222-1, 222-2, and 222-3 may be respectively patterned for the first through third organic light-emitting diodes OLED1, OLED2, and OLED3, and may respectively correspond to the first through third pixel electrodes 210-1, 210-2, and 210-3. The first through third emission layers 222-1, 222-2, and 222-3 may emit light of different wavelength bands. That is, the first through third emission layers 222-1, 222-2, and 222-3 may emit light of different colors. In an embodiment, the first emission layer 222-1 may include an organic material emitting red light, the second emission layer 222-2 may include an organic material emitting green light, and the third emission layer 222-3 may include an organic material emitting blue light. For example, the first emission layer 222-1 may be formed by using, for example, a red dopant, in a certain host material. The second emission layer 222-2 may be formed by using, for example, a green dopant, in a certain host material. The third emission layer 222-3 may be formed by using, for example, a blue dopant, in a certain host material.

In some embodiments, the first emission layer 222-1 may include a first main emission layer 222m-1 and a first auxiliary emission layer 222a-1. The first main emission layer 222m-1 may include, for example, an organic material emitting red light. The first auxiliary emission layer 222a-1 that is, for example, a hole transport layer, may include PEDOT, PANI, TPD, or NPB. For example, the first auxiliary emission layer 222a-1 may include a material different from that of the first common layer 221 described below.

Likewise, the second emission layer 222-2 may include a second main emission layer 222m-2 and a second auxiliary emission layer 222a-2. The second main emission layer 222m-2 may include, for example, an organic material emitting green light. The second auxiliary emission layer 222a-2 that is, for example, a hole transport layer, may include PEDOT, PANI, TPD, or NPB. For example, the second auxiliary emission layer 222a-2 may include a material different from that of the first common layer 221 described below.

In some embodiments, a thickness t1 of the first main emission layer 222m-1 and a thickness t1′ of the first auxiliary emission layer 222a-1 may be different from each other. The thickness t1′ of the first auxiliary emission layer 222a-1 may be determined so that the first emission layer 222-1 has a resonance structure as a whole. Accordingly, the luminous efficiency of the first emission layer 222-1 may be improved. Likewise, a thickness t2 of the second main emission layer 222m-2 and a thickness t2′ of the second auxiliary emission layer 222a-2 may be different from each other, and the thickness t2′ of the second auxiliary emission layer 222a-2 may be determined so that the second emission layer 222-2 has a resonance structure as a whole. Accordingly, the luminous efficiency of the second emission layer 222-2 may be improved.

In some embodiments, the thickness t1′ of the first auxiliary emission layer 222a-1 and the thickness t2′ of the second auxiliary emission layer 222a-2 may be different from each other.

Also, the thickness t1 of the first main emission layer 222m-1, the thickness t2 of the second main emission layer 222m-2, and a thickness t3 of the third emission layer 222-3 may be different from one another. For example, the thickness t1 of the first main emission layer 222m-1 emitting light of a longest wavelength band may be greater than the thickness t2 of the second main emission layer 222m-2 and the thickness t3 of the third emission layer 222-3. The thickness t3 of the third emission layer 222-3 emitting light of a shortest wavelength band may be less than the thickness t1 of the first main emission layer 222m-1 and the thickness t2 of the second main emission layer 222m-2. Because the first through third emission layers 222-1, 222-2, and 222-3 emit light of different wavelength bands, the thickness t1 of the first main emission layer 222m-1, the thickness t2 of the second main emission layer 222m-2, and the thickness t3 of the third emission layer 222-3 may be determined by considering a wavelength band of light emitted by each of the first through third emission layers 222-1, 222-2, and 222-3, thereby improving the luminous efficiency of the first through third emission layers 222-1, 222-2, and 222-3.

In an embodiment, the first common layer 221 may be provided between the first through third pixel electrodes 210-1, 210-2, and 210-3 and the first through third emission layers 222-1, 222-2, and 222-3, and the second common layer 223 may be provided between the first through third emission layers 222-1, 222-2, and 222-3 and the counter electrode 230.

The first common layer 221 may include a hole injection layer HIL and a hole transport layer HTL, and the second common layer 223 may include an electron transport layer ETL and an electron injection layer EIL. Although each of the first through third organic light-emitting diodes OLED1, OLED2, and OLED3 includes the hole injection layer HIL, the hole transport layer HTL, the electron transport layer ETL, and the electron injection layer EIL in FIG. 6, the inventive concepts are not limited thereto. In another embodiment, at least one of the hole injection layer HIL, the hole transport layer HTL, the electron transport layer ETL, and the electron injection layer EIL may be omitted.

The hole injection layer HIL may facilitate hole injection, and may include at least one selected from the group consisting of, but not limited to, hexaazatriphenylene hexacarbonitrile (HAT-CN), copper phthalocyanine (CuPc), PEDOT, PANI, and N,N′-dinaphthyl-N,N′-diphenylbenzidine (NPD). In some embodiments, the hole injection layer HIL may be replaced with the hole transport layer HTL that is p-type doped.

The hole transport layer HTL may include a triphenylamine derivative having high hole mobility and excellent stability, such as PEDOT, PANI, TPD, or NPB, as a host of the hole transport layer.

The electron transport layer ETL may facilitate electron transport, and may include at least one selected from the group consisting of, but not limited to, tris(8-hydroxyquinolinato)aluminum (Alq3), PBD, TAZ, Spiro-PBD, BAlq, lithium quinolate (Liq), BMB-3T, PF-6P, TPBi, COT, and SAlq.

The electron injection layer EIL may facilitate electron injection, and the electron injection layer EIL may use, but is not limited to, Yb, Alq3, PBD, TAZ, spiro-PBD, BAlq, or SAlq.

In an embodiment, the first common layer 221 may be patterned for each of the first through third organic light-emitting diodes OLED1, OLED2, and OLED3. For example, the first common layer 221 may include a 1-1^{st} pattern unit 221a, a 1-2^{nd} pattern unit 221b, and a 1-3^{rd} pattern unit 221c respectively corresponding to the first through third pixel electrodes 210-1, 210-2, and 210-3 and disconnected from one another.

For example, when the first common layer 221 includes the hole injection layer HIL and the hole transport layer HTL, the hole injection layer HIL and the hole transport layer HTL may be patterned for each of the first through third organic light-emitting diodes OLED1, OLED2, and OLED3. For example, the hole injection layer HIL may include a first portion HILa, a second portion HILb, and a third portion HILc respectively corresponding to the first through third pixel electrodes 210-1, 210-2, and 210-3 and disconnected from one another, and the hole transport layer HTL may include a first portion HTLa, a second portion HTL b, and a third portion HTLc respectively corresponding to the first through third pixel electrodes 210-1, 210-2, and 210-3 and disconnected from one another.

Accordingly, the first portion HILa of the hole injection layer HIL and the first portion HTLa of the hole transport layer HTL may constitute the 1-1^{st} pattern unit 221a of the first common layer 221, the second portion HILb of the hole injection layer HIL and the second portion HTLb of the hole transport layer HTL may constitute the 1-2^{nd} pattern unit 221b of the first common layer 221, and the third portion HILc of the hole injection layer HIL and the third portion HTLc of the hole transport layer HTL may constitute the 1-3^{rd} pattern unit 221c of the first common layer 221.

As such, because the first common layer 221 is disconnected for each organic light-emitting diode OLED, leakage current may not occur between adjacent organic light-emitting diodes OLED. That is, driving current supplied to one organic light-emitting diode OLED may be prevented from flowing to another adjacent organic light-emitting diode OLED through the first common layer 221. Accordingly, light emission of the adjacent organic light-emitting diode OLED due to the leakage current may be prevented, and display quality of the display apparatus may be improved.

Furthermore, because the first common layer 221 is completely disconnected for each organic light-emitting diode OLED, although a resolution of the display apparatus 1 increases, the leakage current does not occur. Also, the first common layer 221 may include a material having high electrical conductivity without restrictions. Accordingly, the display apparatus 1 having a high resolution may be implemented, and the display apparatus 1 in which characteristics such as the lifetime and efficiency of the organic light-emitting diode OLED are improved may be implemented.

In an embodiment, the second common layer 223 may be integrally provided over the first through third organic light-emitting diodes OLED1, OLED2, and OLED3.

FIG. 7 is a cross-sectional view illustrating a light-emitting device provided in a display apparatus, according to another embodiment. The same description as that made with reference to FIG. 6 will be omitted, and the following will focus on a difference.

Referring to FIG. 7, the second common layer 223 may also be patterned for each of the first through third organic light-emitting diodes OLED1, OLED2, and OLED3. For example, the second common layer 223 may include a 2-1^{st} pattern unit 223a, a 2-2^{nd} pattern unit 223b, and a 2-3^{rd} pattern unit 223c respectively corresponding to the first through third pixel electrodes 210-1, 210-2, and 210-3 and disconnected from one another.

For example, when the second common layer 223 includes the electron injection layer EIL and the electron transport layer ETL, the electron injection layer EIL and the electron transport layer ETL may be patterned for each of the first through third organic light-emitting diodes OLED1, OLED2, and OLED3. For example, the electron injection layer EIL may include a first portion EILa, a second portion EILb, and a third portion EILc respectively corresponding to the first through third pixel electrodes 210-1, 210-2, and 210-3 and disconnected from one another, and the electron transport layer ETL may include a first portion ETLa, a second portion ETLb, and a third portion ETLc respectively corresponding to the first through third pixel electrodes 210-1, 210-2, and 210-3 and disconnected from one another.

Accordingly, the first portion EILa of the electron injection layer EIL and the first portion ETLa of the electron transport layer ETL may constitute the 2-1^{st} pattern unit 223a of the second common layer 223, the second portion EILb of the electron injection layer EIL and the second portion ETLb of the electron transport layer ETL may constitute the 2-2^{nd} pattern unit 223b of the second common layer 223, and the third portion EILc of the electron injection layer EIL and the third portion ETLc of the electron transport layer ETL may constitute the 2-3^{rd} pattern unit 223c of the second common layer 223.

As such, because the second common layer 223 is disconnected for each organic light-emitting diode OLED, leakage current may not occur between adjacent organic light-emitting diodes OLED. Accordingly, light emission of an adjacent organic light-emitting diode OLED due to leakage current may be prevented, and display quality of the display apparatus may be improved. Also, the display apparatus 1 having a high resolution may be implemented, and the display apparatus 1 in which characteristics such as the lifetime and efficiency of the organic light-emitting diode OLED are improved may be implemented.

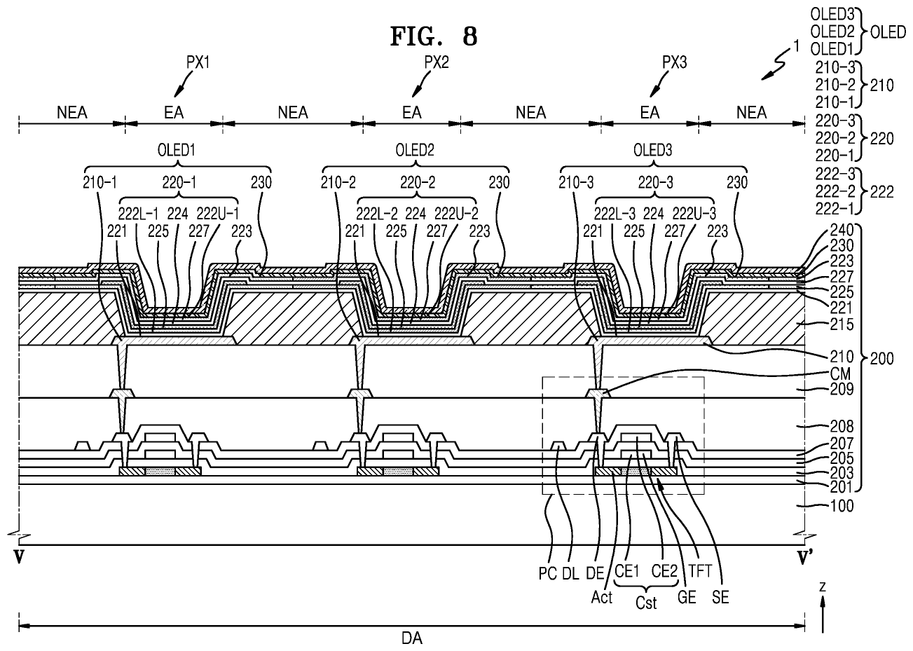

FIG. 8 is a cross-sectional view illustrating a part of a display apparatus, according to another embodiment. FIG. 8 is a modification and is a cross-sectional view taken along line V-V′ of the display apparatus of FIG. 4.

Although FIG. 8 is similar to FIG. 5, FIG. 8 is different from FIG. 5 in structures of the first through third organic light-emitting diodes OLED1, OLED2, and OLED3. The same description as that made with reference to FIG. 5 will be omitted, and the following description will focus on differences between FIG. 5 and FIG. 8.

Referring to FIG. 8, each of the first through third organic light-emitting diodes OLED1, OLED2, and OLED3 may have a tandem structure including a plurality of emission layers.

In an embodiment, the first organic light-emitting diode OLED1 may include the first pixel electrode 210-1, the first intermediate layer 220-1 including a plurality of emission layers, and the counter electrode 230. For example, the first intermediate layer 220-1 of the first organic light-emitting diode OLED1 may include a first lower emission layer 222L-1, and a first upper emission layer 222U-1 located on the first lower emission layer 222L-1 to overlap the first lower emission layer 222L-1.

Likewise, the second organic light-emitting diode OLED2 may include the second pixel electrode 210-2, the second intermediate layer 220-2 including a plurality of emission layers, and the counter electrode 230. For example, the second intermediate layer 220-2 of the second organic light-emitting diode OLED2 may include a second lower emission layer 222L-2, and a second upper emission layer 222U-2 located on the second lower emission layer 222L-2 to overlap the second lower emission layer 222L-2.

The third organic light-emitting diode OLED3 may include the third pixel electrode 210-3, the third intermediate layer 220-3 including a plurality of emission layers, and the counter electrode 230. For example, the third intermediate layer 220-3 of the third organic light-emitting diode OLED3 may include a third lower emission layer 222L-3, and a third upper emission layer 222U-3 located on the third lower emission layer 222L-3 to overlap the third lower emission layer 222L-3.

In an embodiment, the first through third lower emission layers 222L-1, 222L-2, and 222L-3 may be individually provided by being respectively patterned for the first through third organic light-emitting diodes OLED1, OLED2, and OLED3. Also, the first through third upper emission layers 222U-1, 222U-2, and 222U-3 may be individually provided by being respectively patterned for the first through third organic light-emitting diodes OLED1, OLED2, and OLED3.

For example, adjacent lower emission layers 222L-1, 222L-2, and 222L-3 may contact one another in the non-emission area NEA. For example, edges of adjacent lower emission layers 222L-1, 222L-2, and 222L-3 may contact one another, but the inventive concepts are not limited thereto. When the lower emission layers 222L-1, 222L-2, and 222L-3 are formed, adjacent lower emission layers 222L-1, 222L-2, and 222L-3 may partially overlap or may be spaced apart from one another according to a process error. These characteristics may also be applied to the upper emission layers 222U-1, 222U-2, and 222U-3, and thus, a repeated description will be omitted.

In an embodiment, as described above, the first through third organic light-emitting diodes OLED1, OLED2, and OLED3 may emit light of different colors. For example, the first through third organic light-emitting diodes OLED1, OLED2, and OLED3 may respectively emit red light, green light, and blue light. To this end, the first through third lower emission layers 222L-1, 222L-2, and 222L-3 may emit light of different colors. For example, the first through third lower emission layers 222L-1, 222L-2, and 222L-3 may respectively emit red light, green light, and blue light. Also, the first through third upper emission layers 222U-1, 222U-2, and 222U-3 may emit light of different colors. For example, the first through third upper emission layers 222U-1, 222U-2, and 222U-3 may emit red light, green light, and blue light.

That is, the first lower emission layer 222L-1 and the first upper emission layer 222U-1 of the first organic light-emitting diode OLED1 which overlap each other may emit light of the same wavelength band. For example, the first lower emission layer 222L-1 may emit red light and the first upper emission layer 222U-1 may also emit red light. Also, the second lower emission layer 222L-2 and the second upper emission layer 222U-2 of the second organic light-emitting diode OLED2 which overlap each other may emit light of the same wavelength band. For example, the second lower emission layer 222L-2 may emit green light and the second upper emission layer 222U-2 may also emit green light. The third lower emission layer 222L-3 and the third upper emission layer 222U-3 of the third organic light-emitting diode OLED3 which overlap each other may emit light of the same wavelength band. For example, the third lower emission layer 222L-3 may emit blue light and the third upper emission layer 222U-3 may also emit blue light.

In an embodiment, the first through third intermediate layers 220-1, 220-2, and 220-3 may include a charge generation layer 224 located between the first through third lower emission layers 222L-1, 222L-2, and 222L-3 and the first through third upper emission layers 222U-1, 222U-2, and 222U-3. That is, the charge generation layer 224 may be located between the first lower emission layer 222L-1 and the first upper emission layer 222U-1, between the second lower emission layer 222L-2 and the second upper emission layer 222U-2, and between the third lower emission layer 222L-3 and the third upper emission layer 222U-3. The charge generation layer 224 may supply charges to a first stack including the first through third lower emission layers 222L-1, 222L-2, and 222L-3 and a second stack including the first through third upper emission layers 222U-1, 222U-2, and 222U-3.

In an embodiment, the charge generation layer 224 may be individually provided by being patterned for each of the first through third organic light-emitting diodes OLED1, OLED2, and OLED3. For example, the charge generation layer 224 may include a first portion 224a, a second portion 224b, and a third portion 224c respectively corresponding to the first through third lower emission layers 222L-1, 222L-2, and 222L-3 and disconnected from one another. In some embodiments, the charge generation layer 224 may include a plurality of sub-layers, and at least one of the plurality of sub-layers may include a plurality of portions respectively corresponding to the first through third lower emission layers 222L-1, 222L-2, and 222L-3 and disconnected from one another.

The first through third intermediate layers 220-1, 220-2, and 220-3 may include the first common layer 221 located between the first through third pixel electrodes 210-1, 210-2, and 210-3 and the first through third lower emission layers 222L-1, 222L-2, and 222L-3, and the second common layer 223 located between the first through third upper emission layers 222U-1, 222U-2, and 222U-3 and the counter electrode 230. That is, the first through third upper emission layers 222U-1, 222U-2, and 222U-3 may be located under the counter electrode 230 with the second common layer 223 therebetween. The same description as that made with reference to FIG. 5 may apply to the first common layer 221 and the second common layer 223, and thus a repeated description will be omitted.

In an embodiment, the first through third intermediate layers 220-1, 220-2, and 220-3 may further include a third common layer 225 located between the first through third lower emission layers 222L-1, 222L-2, and 222L-3 and the charge generation layer 224, and a fourth common layer 227 located between the charge generation layer 224 and the first through third upper emission layers 222U-1, 222U-2, and 222U-3. In an embodiment, the third common layer 225 may include an electron transport layer, and the fourth common layer 227 may include a hole transport layer.

For example, the first common layer 221, the first lower emission layer 222L-1, the third common layer 225, the charge generation layer 224, the fourth common layer 227, the first upper emission layer 222U-1, and the second common layer 223 may constitute the first intermediate layer 220-1. Likewise, the first common layer 221, the second lower emission layer 222L-2, the third common layer 225, the charge generation layer 224, the fourth common layer 227, the second upper emission layer 222U-2, and the second common layer 223 may constitute the second intermediate layer 220-2, and the first common layer 221, the third lower emission layer 222L-3, the third common layer 225, the charge generation layer 224, the fourth common layer 227, the third upper emission layer 222U-3, and the second common layer 223 may constitute the third intermediate layer 220-3.

The counter electrode 230 of the first through third organic light-emitting diodes OLED1, OLED2, and OLED3 may be located on the first through third upper emission layers 222U-1, 222U-2, and 222U-3. The counter electrode 230 may be integrally formed over the first through third upper emission layers 222U-1, 222U-2, and 222U-3.

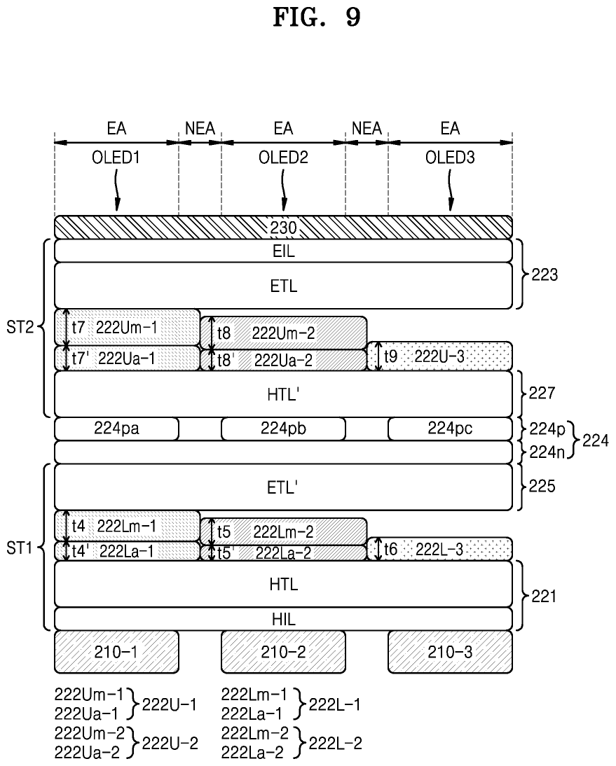

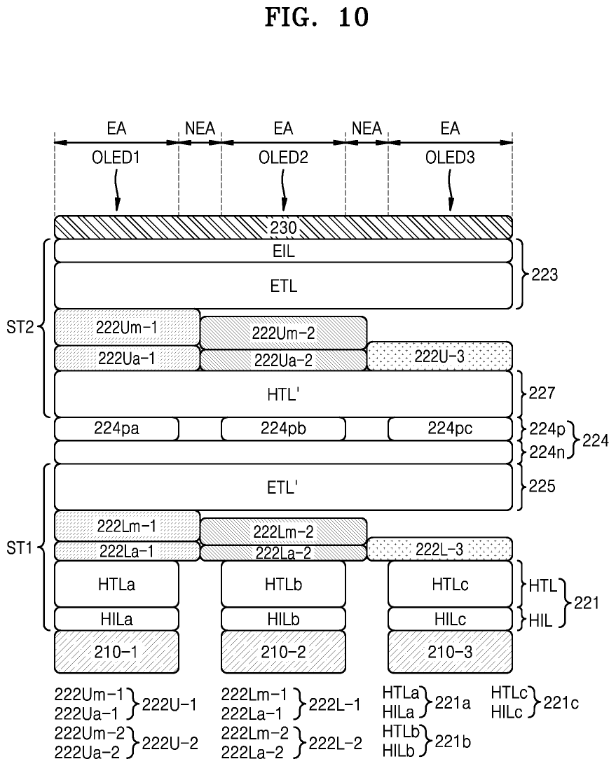

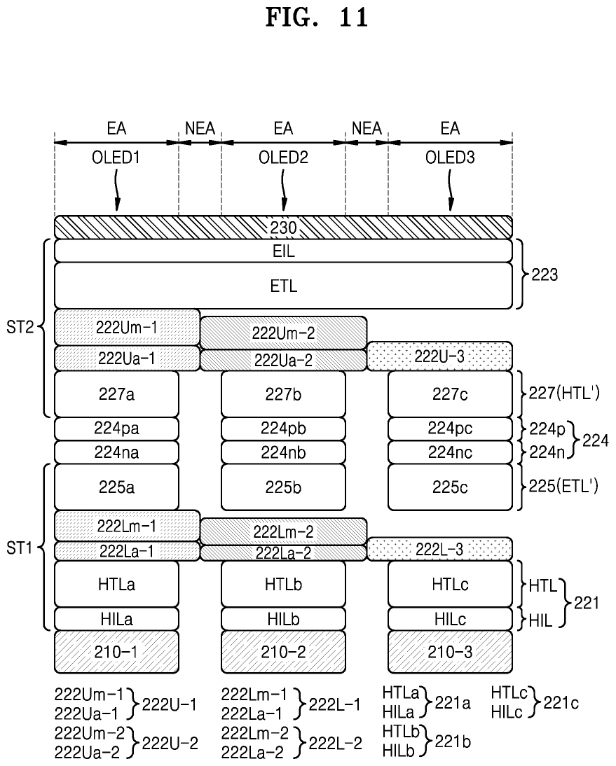

FIG. 9 is a cross-sectional view illustrating a light-emitting device provided in a display apparatus, according to another embodiment. FIG. 9 may correspond to a light-emitting device provided in the display apparatus of FIG. 8.

Referring to FIG. 9, the display apparatus 1 may include the light-emitting diode OLED as a light-emitting device. For example, the display apparatus 1 may include the first through third organic light-emitting diodes OLED1, OLED2, and OLED3 emitting light of different wavelength bands. In an embodiment, each of the first through third organic light-emitting diodes OLED1, OLED2, and OLED3 may have a tandem structure including a plurality of emission layers.

The first through third pixel electrodes 210-1, 210-2, and 210-3 respectively provided in the first through third organic light-emitting diodes OLED1, OLED2, and OLED3 may each be patterned for each emission area EA. That is, the first through third pixel electrodes 210-1, 210-2, and 210-3 may be spaced apart from one another, and may have island shapes (or isolated shapes) in a plan view.

The counter electrode 230 of the first through third organic light-emitting diodes OLED1, OLED2, and OLED3 may be integrally provided over the first through third organic light-emitting diodes OLED1, OLED2, and OLED3.

The first through third organic light-emitting diodes OLED1, OLED2, and OLED3 may respectively include the first through third lower emission layers 222L-1, 222L-2, and 222L-3 located between the first through third pixel electrodes 210-1, 210-2, and 210-3 and the counter electrode 230. The first through third lower emission layers 222L-1, 222L-2, and 222L-3 may be patterned for the first through third organic light-emitting diodes OLED1, OLED2, and OLED3, and may respectively correspond to the first through third pixel electrodes 210-1, 210-2, and 210-3.

The first through third lower emission layers 222-1, 222-2, and 222-3 may emit light of different wavelength bands. That is, the first through third lower emission layers 222L-1, 222L-2, and 222L-3 may emit light of different colors. In an embodiment, the first lower emission layer 222L-1 may include an organic material emitting red light, the second lower emission layer 222L-2 may include an organic material emitting green light, and the third lower emission layer 222L-3 may include an organic material emitting blue light. For example, the first lower emission layer 222L-1 may be formed by using, for example, a red dopant, in a certain host material. The second lower emission layer 222L-2 may be formed by using, for example, a green dopant, in a certain host material. The third lower emission layer 222L-3 may be formed by using, for example, a blue dopant, in a certain host material.

In some embodiments, the first lower emission layer 222L-1 may include a first main lower emission layer 222Lm-1 and a first auxiliary lower emission layer 222La-1. The first main lower emission layer 222Lm-1 may include, for example, an organic material emitting red light. The first auxiliary lower emission layer 222La-1 that is, for example, a hole transport layer may include PEDOT, PANI, TPD, or NPB. For example, the first auxiliary lower emission layer 222La-1 may include a material different from that of the first common layer 221.

Likewise, the second lower emission layer 222L-2 may include a second main lower emission layer 222Lm-2 and a second auxiliary lower emission layer 222La-2. The second main lower emission layer 222Lm-2 may include, for example, an organic material emitting green light. The second auxiliary lower emission layer 222La-2 that is, for example, a hole transport layer, may include PEDOT, PANI, TPD, or NPB. For example, the second auxiliary lower emission layer 222La-2 may include a material different from that of the first common layer 221 described below.

In some embodiments, a thickness t4 of the first main lower emission layer 222Lm-1 of the first lower emission layer 222L-1 and a thickness t4′ of the first auxiliary lower emission layer 222La-1 may be different from each other. The thickness t4′ of the first auxiliary lower emission layer 222La-1 may be determined so that the first lower emission layer 222L-1 has a resonance structure as a whole. Accordingly, the luminous efficiency of the first lower emission layer 222L-1 may be improved. Likewise, a thickness t5 of the second main lower emission layer 222Lm-2 and a thickness t5′ of the second auxiliary lower emission layer 222La-2 may be different from each other, and the thickness t5′ of the second auxiliary lower emission layer 222La-2 may be determined so that the second lower emission layer 222L-2 has a resonance structure as a whole. Accordingly, the luminous efficiency of the second lower emission layer 222L-2 may be improved.

In some embodiments, the thickness t4′ of the first auxiliary lower emission layer 222La-1 and the thickness t5′ of the second auxiliary lower emission layer 222La-2 may be different from each other.

Also, the thickness t4 of the first main lower emission layer 222Lm-1, the thickness t5 of the second main lower emission layer 222Lm-2, and a thickness t6 of the third lower emission layer 222-3 may be different from one another. For example, the thickness t4 of the first main lower emission layer 222Lm-1 emitting light of a longest wavelength band may be greater than the thickness t5 of the second main lower emission layer 222Lm-2 and the thickness t6 of the third lower emission layer 222L-3. The thickness T6 of the third lower emission layer 222L-3 emitting light of a shortest wavelength band may be less than the thickness t4 of the first main lower emission layer 222Lm-1 and the thickness t5 of the second main lower emission layer 222Lm-2. Because the first through third lower emission layers 222L-1, 222L-2, and 222L-3 emit light of different wavelength bands, the thickness t4 of the first main lower emission layer 222Lm-1, the thickness t5 of the second main lower emission layer 222Lm-2, and the thickness t6 of the third lower emission layer 222-3 may be determined by considering a wavelength band of light emitted by each of the first through third lower emission layers 222L-1, 222L-2, and 222L-3, thereby improving the luminous efficiency of the first through third lower emission layers 222L-1, 222L-2, and 222L-3.

In an embodiment, the first through third organic light-emitting diodes OLED1, OLED2, and OLED3 may respectively include the first through third upper emission layers 222U-1, 222U-2, and 222U-3 located between the first through third lower emission layers 222L-1, 222L-2, and 222L-3 and the counter electrode 230. The first through third upper emission layers 222U-1, 222U-2, and 222U-3 may be patterned for the first through third organic light-emitting diodes OLED1, OLED2, and OLED3, and may respectively overlap the first through third lower emission layers 222L-1, 222L-2, and 222L-3.

In an embodiment, the first through third upper emission layers 222U-1, 222U-2, and 222U-3 and the first through third lower emission layers 222L-1, 222L-2, and 222L-3 may emit light of the same wavelength bands. For example, the first through third upper emission layers 222U-1, 222U-2, and 222U-3 and the first through third lower emission layers 222L-1, 222L-2, and 222L-3 may include the same materials.

In some embodiments, the first upper emission layer 222U-1 may include a first main upper emission layer 222Um-1 and a first auxiliary upper emission layer 222Ua-1. The first main upper emission layer 222Um-1 may include, for example, an organic material emitting red light. The first auxiliary upper emission layer 222Ua-1 that is, for example, a hole transport layer may include PEDOT, PANI, TPD, or NPB. For example, the first auxiliary upper emission layer 222Ua-1 may include a material different from that of the first common layer 221.

Likewise, the second upper emission layer 222U-2 may include a second main upper emission layer 222Um-2 and a second auxiliary upper emission layer 222Ua-2. The second main upper emission layer 222Um-2 may include, for example, an organic material emitting green light. The second auxiliary upper emission layer 222Ua-2 that is, for example, a hole transport layer may include PEDOT, PANI, TPD, or NPB. For example, the second auxiliary upper emission layer 222Ua-2 may include a material different from that of the first common layer 221 described below.

In some embodiments, a thickness t7 of the first main upper emission layer 222Um-1 of the first upper emission layer 222U-1 and a thickness t7′ of the first auxiliary upper emission layer 222Ua-1 may be different from each other. The thickness t7′ of the first auxiliary upper emission layer 222Ua-1 may be determined so that the first upper emission layer 222U-1 has a resonance structure as a whole. Accordingly, the luminous efficiency of the first upper emission layer 222U-1 may be improved. Likewise, a thickness t8 of the second main upper emission layer 222Um-2 and a thickness t8′ of the second auxiliary upper emission layer 222Ua-2 may be different from each other, and the thickness t8′ of the second auxiliary upper emission layer 222Ua-2 may be determined so that the second upper emission layer 222U-2 has a resonance structure as a whole. Accordingly, the luminous efficiency of the second upper emission layer 222U-2 may be improved.

In some embodiments, the thickness t7′ of the first auxiliary upper emission layer 222Ua-1 and the thickness t8′ of the second auxiliary upper emission layer 222Ua-2 may be different from each other.

Also, the thickness t7 of the first main upper emission layer 222Um-1, the thickness t8 of the second main upper emission layer 222Um-2, and a thickness t9 of the third upper emission layer 222-3 may be different from one another. For example, the thickness t7 of the first main upper emission layer 222Um-1 emitting light of a longest wavelength band may be greater than the thickness t8 of the second main upper emission layer 222Um-2 and the thickness t9 of the third upper emission layer 222U-3. The thickness t9 of the third upper emission layer 222U-3 emitting light of a shortest wavelength band may be less than the thickness t7 of the first main upper emission layer 222Um-1 and the thickness t8 of the second main upper emission layer 222Um-2. Because the first through third upper emission layers 222U-1, 222U-2, and 222U-3 emit light of different wavelength bands, the thickness t7 of the first main upper emission layer 222Um-1, the thickness t8 of the second main upper emission layer 222Um-2, and the thickness t9 of the third upper emission layer 222-3 may be determined by considering a wavelength band of light emitted by each of the first through third upper emission layers 222U-1, 222U-2, and 222U-3, thereby improving the luminous efficiency of the first through third upper emission layers 222U-1, 222U-2, and 222U-3. For example, a thickness of the first lower emission layer 222L-1 and a thickness of the first upper emission layer 222U-1 may be different from each other, a thickness of the second lower emission layer 222L-2 and a thickness of the second upper emission layer 222U-2 may be different from each other, and a thickness of the third lower emission layer 222L-3 and a thickness of the third upper emission layer 222U-3 may be different from each other.

For example, the thickness t4 of the first main lower emission layer 222Lm-1 and the thickness t4′ of the first auxiliary lower emission layer 222La-1 of the first lower emission layer 222L-1, and the thickness t7 of the first main upper emission layer 222Um-1 and the thickness t7′ of the first auxiliary upper emission layer 222Ua-1 of the first upper emission layer 222U-1 may be different from each other. Likewise, the thickness 54 of the second main lower emission layer 222Lm-2 and the thickness t5′ of the second auxiliary lower emission layer 222La-2 of the second lower emission layer 222L-2, and the thickness t8 of the second main upper emission layer 222Um-2 and the thickness t8′ of the second auxiliary upper emission layer 222Ua-2 of the second upper emission layer 222U-2 may be different from each other. Also, the thickness t6 of the third lower emission layer 222L-3 and the thickness t9 of the third upper emission layer 222U-3 may be different from each other.

In an embodiment, the charge generation layer 224 may be provided between the first through third lower emission layers 222L-1, 222L-2, and 222L-3 and the first through third upper emission layers 222U-1, 222U-2, and 222U-3. The charge generation layer 224 may supply charges to a first stack ST1 including the first through third lower emission layers 222L-1, 222L-2, and 222L-3 and a second stack ST2 including the first through third upper emission layers 222U-1, 222U-2, and 222U-3.

For example, the charge generation layer 224 may include an n-type charge generation layer 224n for supplying electrons to the first stack ST1 and a p-type charge generation layer 224p for supplying holes to the second stack ST2.

The n-type charge generation layer 224n may include an n-type dopant material and an n-type host material. The n-type dopant material may be an organic material or a mixture thereof, which may inject group 1 and 2 metals or electrons in the periodic table. For example, the n-type dopant material may be any one of an alkali metal and an alkaline-earth metal. That is, the n-type charge generation layer 224n may include, but is not limited to, an organic layer doped with an alkali metal such as lithium (Li), sodium (Na), potassium (K), or cesium (Cs), or an alkaline-earth metal such as magnesium (Mg), strontium (Sr), barium (Ba) or radium (Ra). The n-type host material may include a material that may transport electrons. For example, the n-type host material may include at least one of, but not limited to, Alq3, 8-hydroxyquinolinolato-lithium (Liq), 2-(4-biphenylyl)-5-(4-tert-butylphenyl)-1,3,4-oxadiazole (PBD), 3-(4-biphenyl)-4-phenyl-5-tert-butylphenyl-1,2,4-triazole (TAZ), Spiro-PBD, bis(2-methyl-8-quinolinolate)-4-(phenylphenolato)aluminum (BAlq), SAlq, 2,2′,2″-(1,3,5-benzinetriyl)-tris(1-phenyl-1-H-benzimidazole) (TPBi), oxadiazole, triazole, phenanthroline, benzoxazole, and benzthiazole.

The p-type charge generation layer 224p may include a p-type dopant material and a p-type host material. The p-type dopant material may include, but is not limited thereto, a metal oxide, an organic material such as a tetrafluoro-tetracyanoquinodimethane (F4-TCNQ), hexaazatriphenylene-hexacarbonitrile (HAT-CN), or hexaazatriphenylene, or a metal material such as V₂O₅, MoOx, or WO₃. The p-type host material may include a material that may transport holes. For example, the p-type host material may include at least one of, but not limited to, N,N-dinaphthyl-N,N′-diphenyl benzidine (N,N-bis(naphthalene-1-yl)-N,N′-bis(phenyl)-2,2′-dimethylbenzidine) (NPD), N,N′-bis-(3-methylphenyl)-N,N′-bis-(phenyl)-benzidine (TPD), and 4,4′,4″-Tris(N-3-methylphenyl-N-phenyl-amino)-triphenylamine (MTDATA).

In an embodiment, the charge generation layer 224 may include a plurality of portions respectively corresponding to the first through third lower emission layers 222L-1, 222L-2, and 222L-3 and disconnected from one another. For example, when the charge generation layer 224 includes the n-type charge generation layer 224n and the p-type charge generation layer 224p, at least one of the n-type charge generation layer 224n and the p-type charge generation layer 224p may include a first portion, a second portion, and a third portion respectively corresponding to the first through third lower emission layers 222L-1, 222L-2, and 222L-3 and disconnected from one another. For example, in FIG. 9, the p-type charge generation layer 224p includes a first portion 224pa, a second portion 224pb, and a third portion 224pc respectively corresponding to the first through third lower emission layers 222L-1, 222L-2, and 222L-3 and disconnected from one another.

As a comparative example, when the charge generation layer 224 is integrally formed over the plurality of organic light-emitting diodes OLED, leakage current may flow between adjacent organic light-emitting diodes OLED through the charge generation layer 224, thereby reducing display quality.

However, according to an embodiment, because the charge generation layer 224 is disconnected for each organic light-emitting diode OLED, leakage current between adjacent organic light-emitting diodes OLED may be prevented. Accordingly, light emission of an adjacent organic light-emitting diode OLED due to leakage current may be prevented, and display quality of the display apparatus may be improved. Also, the display apparatus 1 having a high resolution may be implemented, and the display apparatus 1 in which characteristics such as the lifetime and efficiency of the organic light-emitting diode OLED are improved may be implemented.

The first common layer 221 may be located between the first through third pixel electrodes 210-1, 210-2, and 210-3 and the first through third lower emission layers 222L-1, 222L-2, and 222L-3, and the second common layer 223 may be located between the first through third lower emission layers 222L-1, 222L-2, and 222L-3 and the counter electrode 230.

The first common layer 221 may include the hole injection layer HIL and the hole transport layer HTL, and the second common layer 223 may include the electron transport layer ETL and the electron injection layer EIL. Although each of the first through third organic light-emitting diodes OLED1, OLED2, and OLED3 includes the hole injection layer HIL, the hole transport layer HTL, the electron transport layer ETL, and the electron injection layer EIL in FIG. 9, the disclosure is not limited thereto. In another embodiment, at least one of the hole injection layer HIL, the hole transport layer HTL, the electron transport layer ETL, and the electron injection layer EIL may be omitted. The hole injection layer HIL, the hole transport layer HTL, the electron transport layer ETL, and the electron injection layer EIL of FIG. 9 are the same as those of FIG. 6, and thus, a repeated description will be omitted.

Also, in an embodiment, the third common layer 225 may be located between the first through third lower emission layers 222L-1, 222L-2, and 222L-3 and the charge generation layer 224, and the fourth common layer 227 may be located between the charge generation layer 224 and the first through third upper emission layers 222U-1, 222U-2, and 222U-3. For example, the third common layer 225 may include an electron transport layer ETL′ located between the first through third lower emission layers 222L-1, 222L-2, and 222L-3 and the n-type charge generation layer 224n, and the fourth common layer 227 may include a hole transport layer HTL′ located between the p-type charge generation layer 224p and the first through third upper emission layers 222U-1, 222U-2, and 222U-3. The electron transport layer ETL′ of the third common layer 225 is the same as or similar to the electron transport layer ETL of the second common layer 223, and the hole transport layer HTL′ of the fourth common layer 227 is the same as or similar to the hole transport layer HTL of the first common layer 221, and thus, a repeated description will be omitted.

For example, the first through fourth common layers 221, 223, 225, and 227 may be integrally provided over the first through third organic light-emitting diodes OLED1, OLED2, and OLED3. In this case, the first through third organic light-emitting diodes OLED1, OLED2, and OLED3 may commonly include the first common layer 221 located between the first through third pixel electrodes 210-1, 210-2, and 210-3 and the first through third lower emission layers 222L-1, 222L-2, and 222L-3, the second common layer 223 located between the first through third upper emission layers 222U-1, 222U-2, and 222U-3 and the counter electrode 230, the third common layer 225 located between the first through third lower emission layers 222L-1, 222L-2, and 222L-3 and the charge generation layer 224, and the fourth common layer 227 located between the charge generation layer 224 and the first through third upper emission layers 222U-1, 222U-2, and 222U-3.

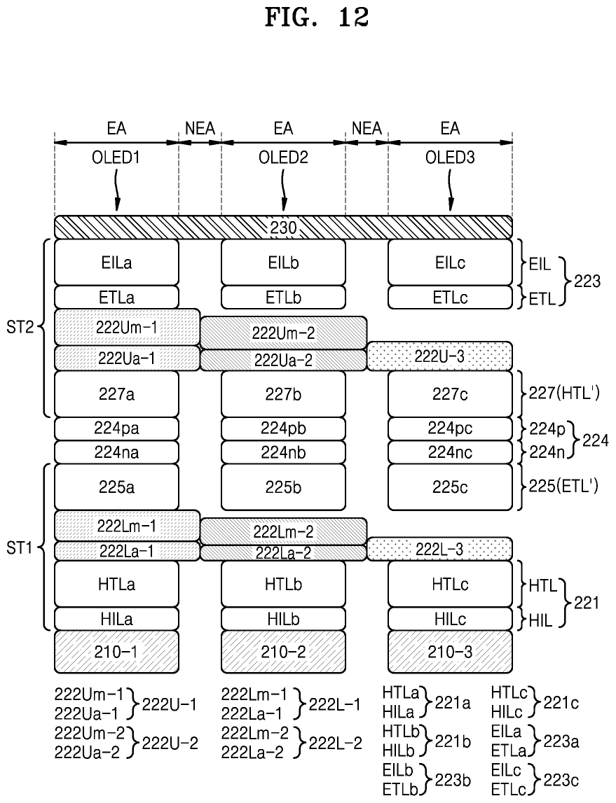

FIG. 10 is a cross-sectional view illustrating a light-emitting device provided in a display apparatus, according to another embodiment. FIG. 10 may correspond to a light-emitting device provided in the display apparatus of FIG. 8. The same description as that made with reference to FIG. 9 will be omitted, and the following will focus on differences between FIG. 9 and FIG. 10.

Referring to FIG. 10, the first common layer 221 may be patterned for each of the first through third organic light-emitting diodes OLED1, OLED2, and OLED3. For example, the first common layer 221 may include the 1-1^{st} pattern unit 221a, the 1-2^{nd} pattern unit 221b, and the 1-3^{rd} pattern unit 221c respectively corresponding to the first through third pixel electrodes 210-1, 210-2, and 210-3 and disconnected from one another.

For example, when the first common layer 221 includes the hole injection layer HIL and the hole transport layer HTL, the hole injection layer HIL and the hole transport layer HTL may be patterned for each of the first through third organic light-emitting diodes OLED1, OLED2, and OLED3. For example, the hole injection layer HIL may include the first portion HILa, the second portion HILb, and the third portion HILc respectively corresponding to the first through third pixel electrodes 210-1, 210-2, and 210-3 and disconnected from one another, and the hole transport layer HTL may include the first portion HTLa, the second portion HTLb, and the third portion HTLc respectively corresponding to the first through third pixel electrodes 210-1, 210-2, and 210-3 and disconnected from one another. Accordingly, the first portion HILa of the hole injection layer HIL and the first portion HTLa of the hole transport layer HTL may constitute the 1-1^{st} pattern unit 221a, the second portion HILb of the hole injection layer HIL and the second portion HTLb of the hole transport layer HTL may constitute the 1-2^{nd} pattern unit 221b of the first common layer 221, and the third portion HILc of the hole injection layer HIL and the third portion HTLc of the hole transport layer HTL may constitute the 1-3^{rd} pattern unit 221c of the first common layer 221.

As such, because the first common layer 221 is disconnected for each organic light-emitting diode OLED, leakage current may not occur between adjacent organic light-emitting diodes OLED. That is, driving current supplied to one organic light-emitting diode OLED may be prevented from flowing to another adjacent organic light-emitting diode OLED through the first common layer 221. Accordingly, light emission of the adjacent organic light-emitting diode OLED due to the leakage current may be prevented, and display quality of the display apparatus may be improved.

Furthermore, because the first common layer 221 is completely disconnected for each organic light-emitting diode OLED, although a resolution of the display apparatus 1 increases, the leakage current does not occur. Also, the first common layer 221 may include a material having high electrical conductivity without restrictions. Accordingly, the display apparatus 1 having a high resolution may be implemented, and the display apparatus 1 in which characteristics such as the lifetime and efficiency of the organic light-emitting diode OLED are improved may be implemented.

FIG. 11 is a cross-sectional view illustrating a light-emitting device provided in a display apparatus, according to another embodiment. FIG. 11 may correspond to a light-emitting device provided in the display apparatus of FIG. 8. The same description as that made with respect to FIGS. 9 and 10 will be omitted, and the following will focus on differences between FIGS. 9 and 10 and FIG. 11.

Referring to FIG. 11, the charge generation layer 224 may be patterned for each of the first through third organic light-emitting diodes OLED1, OLED2, and OLED3. For example, the p-type charge generation layer 224p of the charge generation layer 224 may include the first portion 224pa, the second portion 224pb, and the third portion 224pc respectively corresponding to the first through third lower emission layers 222L-1, 222L-2, and 222L-3 and disconnected from one another, and the n-type charge generation layer 224n of the charge generation layer 224 may include a first portion 224na, a second portion 224nb, and a third portion 224nc respectively corresponding to the first through third lower emission layers 222L-1, 222L-2, and 222L-3 and disconnected from one another.

Also, each of the third common layer 225 and the fourth common layer 227 may be patterned for each of the first through third organic light-emitting diodes OLED1, OLED2, and OLED3. For example, the third common layer 225 may include a 3-1^{st} pattern unit 225a, a 3-2^{nd} pattern unit 225b, and a 3-3^{rd} pattern unit 225c respectively corresponding to the first through third pixel electrodes 210-1, 210-2, and 210-3 and disconnected from one another, and the fourth common layer 227 may include a 4-1^{st} pattern unit 227a, a 4-2^{nd} pattern unit 227b, and a 4-3^{rd} pattern unit 227c respectively corresponding to the first through third pixel electrodes 210-1, 210-2, and 210-3 and disconnected from one another.

Although each of the p-type charge generation layer 224p and the n-type charge generation layer 224n of the charge generation layer 224, the third common layer 225, and the fourth common layer 227 includes portions patterned for the first through third organic light-emitting diodes OLED1, OLED2, and OLED3 and disconnected from one another in FIG. 11, the inventive concepts are not limited thereto. At least one of the p-type charge generation layer 224p and the n-type charge generation layer 224n of the charge generation layer 224, the third common layer 225, and the fourth common layer 227 may be patterned. However, some of the layers 224p, 224n, 225, and 227 may be patterned together, by considering various conditions of a patterning process (e.g., materials of formed layers).

As such, because each of the p-type charge generation layer 224p and the n-type charge generation layer 224n of the charge generation layer 224, the third common layer, and the fourth common layer 227 is disconnected for each organic light-emitting diode OLED, leakage current may not occur between adjacent organic light-emitting diodes OLED. Accordingly, light emission of an adjacent organic light-emitting diode OLED due to leakage current may be prevented, and display quality of the display apparatus may be improved. Also, the display apparatus 1 having a high resolution may be implemented, and the display apparatus 1 in which characteristics, such as the lifetime and efficiency of the organic light-emitting diode OLED, are improved may be implemented.

FIG. 12 is a cross-sectional view illustrating a light-emitting device provided in a display apparatus, according to another embodiment. FIG. 12 may correspond to a light-emitting device provided in the display apparatus of FIG. 8. The same description as that made with reference to FIGS. 9 through 11 will be omitted, and the following will focus on differences between FIGS. 9-11 and FIG. 12.

Referring to FIG. 12, the second common layer 223 may also be patterned for each of the first through third organic light-emitting diodes OLED1, OLED2, and OLED3. For example, the second common layer 223 may include the 2-1^{st} pattern unit 223a, the 2-2^{nd} pattern unit 223b, and the 2-3^{rd} pattern unit 223c respectively corresponding to the first through third pixel electrodes 210-1, 210-2, and 210-3 and disconnected from one another.

For example, when the second common layer 223 includes the electron injection layer EIL and the electron transport layer ETL, the electron injection layer EIL and the electron transport layer ETL may be patterned for each of the first through third organic light-emitting diodes OLED1, OLED2, and OLED3. For example, the electron injection layer EIL may include the first portion EILa, the second portion EILb, and the third portion EILc respectively corresponding to the first through third pixel electrodes 210-1, 210-2, and 210-3 and disconnected from one another, and the electron transport layer ETL may include the first portion ETLa, the second portion ETLb, and the third portion ETLc respectively corresponding to the first through third pixel electrodes 210-1, 210-2, and 210-3 and disconnected from one another. Accordingly, the first portion EILa of the electron injection layer EIL and the first portion ETLa of the electron transport layer ETL may constitute the 2-1^{st} pattern unit 223a, the second portion EILb of the electron injection layer EIL and the second portion ETLb of the electron transport layer ETL may constitute the 2-2^{nd} pattern unit 223b of the second common layer 223, and the third portion EILc of the electron injection layer EIL and the third portion ETLc of the electron transport layer ETL may constitute the 2-3^{rd} pattern unit 223c of the second common layer 223.

As such, because the second common layer 223 is disconnected for each organic light-emitting diode OLED, leakage current may not occur between adjacent organic light-emitting diodes OLED. Accordingly, light emission of an adjacent organic light-emitting diode OLED due to leakage current may be prevented, and display quality of the display apparatus may be improved. Also, the display apparatus 1 having a high resolution may be implemented, and the display apparatus 1 in which characteristics such as the lifetime and efficiency of the organic light-emitting diode OLED are improved may be implemented.

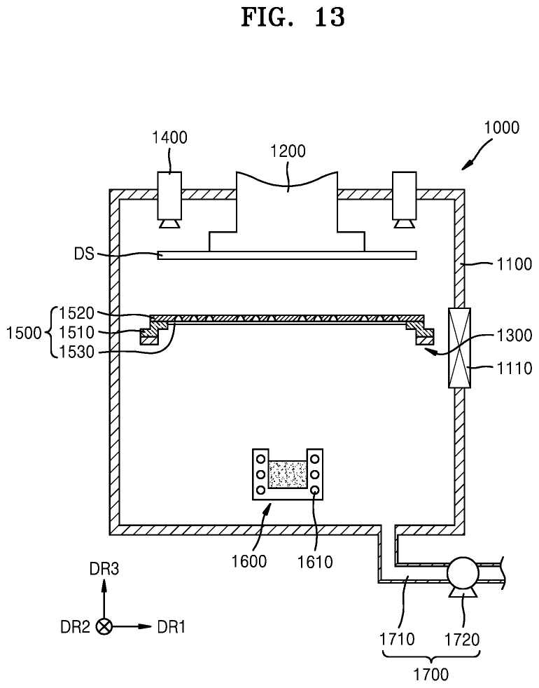

FIG. 13 is a cross-sectional view illustrating an apparatus for manufacturing a display apparatus, according to an embodiment.

Referring to FIG. 13, an apparatus 1000 for manufacturing a display apparatus may include a chamber 1100, a first support 1200, a second support 1300, a vision unit 1400, a mask assembly 1500, a deposition source 1600, and a pressure regulator 1700.

The chamber 1100 may have an inner space therein, and may have an open portion. A gate valve 1110 may be provided in the open portion of the chamber 1100 to selectively open or close the open portion of the chamber 1100.

The first support 1200 may support a display substrate DS. In this case, the first support 1200 may support the display substrate DS by using any of various methods. For example, the first support 1200 may include an electrostatic chuck or an adhesive chuck. In another embodiment, the first support 1200 may include a bracket, a clamp, or the like for supporting a part of the display substrate DS. The first support 1200 is not limited thereto, and may include any device capable of supporting the display substrate DS. However, for convenience of explanation, the following will be described in detail assuming that the first support 1200 includes an electrostatic chuck or an adhesive chuck.

The mask assembly 1500 may be placed and supported on the second support 1300. In this case, the mask assembly 1500 on the second support 1300 may be finally adjusted in at least two different directions.

The vision unit 1400 may capture images of positions of the display substrate DS and the mask assembly 1500. In this case, the display substrate DS and the mask assembly 1500 may be aligned with each other by moving at least one of the display substrate DS and the mask assembly 1500 based on the images captured by the vision unit 1400. That is, the mask assembly 1500 may be aligned with the display substrate DS.

The deposition source 1600 may be located opposite to the display substrate DS with the mask assembly 1500 therebetween. A deposition material may be inserted into the deposition source 1600 and then may be evaporated. In this case, the deposition source 1600 may include a heater 1610, and the deposition material may be evaporated due to heat applied by the heater 1610.

The deposition source 1600 may be formed in any of various types. For example, the deposition source 1600 may be a point deposition source that includes a circular inlet portion through which the deposition material is ejected. Also, the deposition source 1600 may be a linear deposition source that is relatively long and includes a plurality of inlet portions or an inlet portion having a long hole shape.

The pressure regulator 1700 may be connected to the chamber 1100 and may adjust pressure inside the chamber 1100 to be similar to atmospheric pressure or vacuum. In this case, the pressure regulator 1700 may include a connection pipe 1710 connected to the chamber 1100 and a pressure control pump 1720 located in the connection pipe 1710.

A method of manufacturing the display apparatus 1 (see FIG. 1) by using the apparatus 1000 will be described. The display substrate DS may be manufactured and prepared. The display substrate DS may be in a state before the display apparatus 1 is completely manufactured, that is, in a state where the substrate 100 (see FIG. 5) and a part of the display layer 200 on the substrate 100 are formed. For example, the display substrate DS may be in a state where up to the pixel electrode 210 (see FIG. 5) and the pixel-defining film 215 on the pixel electrode 210 are formed.

The pressure regulator 1700 may maintain the inside of the chamber 1100 at atmospheric pressure, and after the gate value 1110 is opened, the display substrate DS and the mask assembly 1500 may be inserted into the chamber 1100. In this case, a separate robotic arm, a shuttle, or the like may be provided inside or outside the chamber 1100 to move the display substrate DS and the mask assembly 1500.

When the above process is completed, the pressure regulator 1700 may maintain the inside of the chamber 1100 at almost vacuum. Also, the vision unit 1400 may capture images of the display substrate DS and the mask assembly 1500, to finely drive the first support 1200 and the second support 1300, finely adjust at least one of the display substrate DS and the mask assembly 1500, and align the display substrate DS and the mask assembly 1500.

The heater 1610 may operate to supply the deposition material from the deposition source 1600 to the mask assembly 1500. The deposition material passing through the mask assembly 1500 may be deposited on the display substrate DS in a certain pattern. For example, the deposition material may be a material for forming any one of the first through fourth common layers 221, 223, 225, and 227 (see FIGS. 5 and 8) of the display layer 200 and the charge generation layer 224 (see FIG. 8).

During the above process, at least one of the deposition source 1600 and the display substrate DS may linearly move. In another embodiment, deposition may be performed in a state where both the deposition source 1600 and the display substrate DS are stopped.

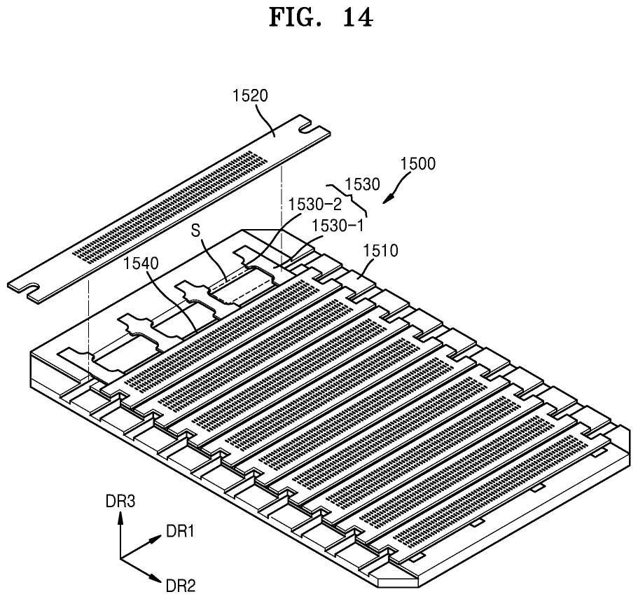

A structure of the mask assembly 1500 used in the apparatus 1000 will now be described in detail with reference to FIG. 14.

FIG. 14 is a perspective view illustrating a mask assembly, according to an embodiment. The mask assembly 1500 of FIG. 14 is used to manufacture the display apparatus 1 of FIG. 1.

Referring to FIG. 14, the mask assembly 1500 may include a mask frame 1510, a mask sheet 1520, a covering plate 1530, and a support frame 1540.

The mask sheet 1520 may be located on the mask frame 1510. At least two mask sheets 1520 may be provided, and may be located on the mask frame 1510 to be spaced apart from each other. The mask sheet 1520 may extend in a first direction DR1, and two or more mask sheets 1520 may be arranged in a second direction DR2. A plurality of opening portions that are spaced apart from one another may be formed in the mask sheet 1520.

The covering plate 1530 may be provided on the mask frame 1510. In this case, a plurality of covering plates 1530 may be provided, and may be located on the mask frame 1510 to be spaced apart from one another. A deposition area S may be defined between the covering plates 1530 that are spaced apart from one another. The deposition area S may have any of various shapes such as a triangular shape, a polygonal shape, an elliptical shape, or a circular shape, as well as a rectangular shape or a square shape.

The covering plate 1530 may include a covering plate body portion 1530-1 provided on the mask frame 1510, and a first covering portion 1530-2 protruding from the covering plate body portion 1530-1.

The covering plate body portion 1530-1 may have a straight plate shape. In this case, the covering plate body portions 1530-1 may be arranged in a direction (e.g., the second direction DR2) perpendicular to a longitudinal direction (e.g., the first direction DR1) of the mask sheet 1520.

The first covering portion 1530-2 may protrude in the longitudinal direction of the mask sheet 1520 from the covering plate body portion 1530-1. In this case, the first covering portion 1530-2 may define an edge of the deposition area S along with the covering plate body portion 1530-1. The first covering portion 1530-2 may define a portion of the edge of the deposition area S which has a certain angle with respect to the covering plate body portion 1530-1, that is, a curved portion.

The covering plate 1530 and the mask sheet 1520 may be formed of different materials. For example, the covering plate 1530 may include austenitic stainless steels0, and the mask sheet 1520 may include a nickel-iron alloy (Invar0).

The covering plate 1530 and the mask sheet 1520 may be stretched and fixed to the mask frame 1510. In this case, the covering plate 1530 and the mask sheet 1520 may be fixed to the mask frame 1510 by using welding.

The support frame 1540 may be located between adjacent mask sheets 1520. The support frame 1540 may be provided so that both ends of the support frame 1540 are inserted into the mask frames 1510. In this case, the support frame 1540 may block a gap between the mask sheets 1520 and support the mask sheets 1520, thereby preventing the mask sheets 1520 from sagging.

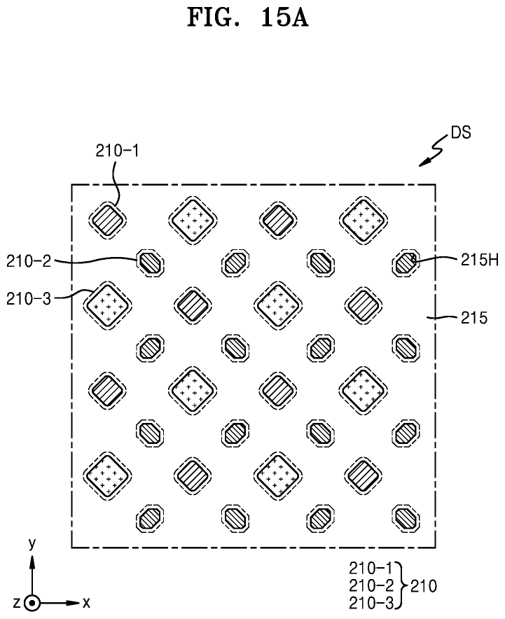

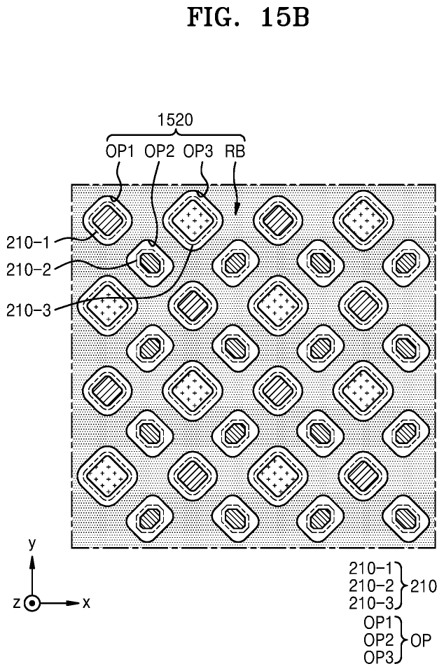

The deposition material may pass through the plurality of opening portions of the mask sheet 1520 located in the deposition area S and may reach the display substrate DS (see FIG. 13). That is, the deposition material may be deposited on the display substrate DS in a certain pattern according to a pattern of the plurality of opening portions of the mask sheet 1520. The plurality of opening portions of the mask sheet 1520 used to form any one of the first through fourth common layers 221, 223, 225, and 227 (see FIGS. 5 and 8) and the charge generation layer 224 (see FIG. 8) of the display apparatus 1 will now be described with reference to FIGS. 15A through 17B.

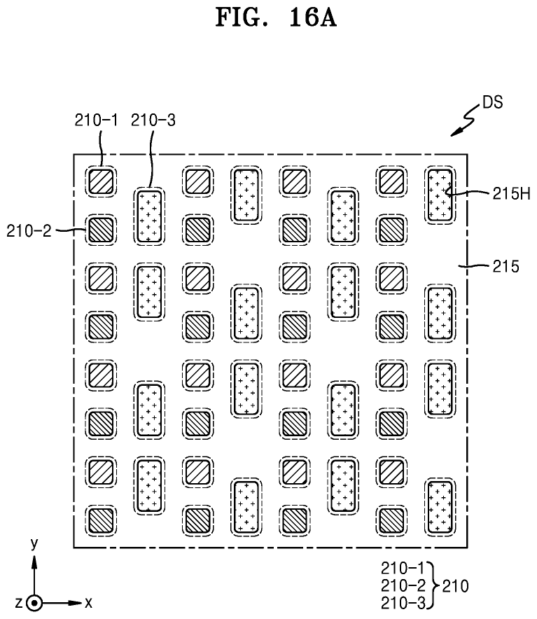

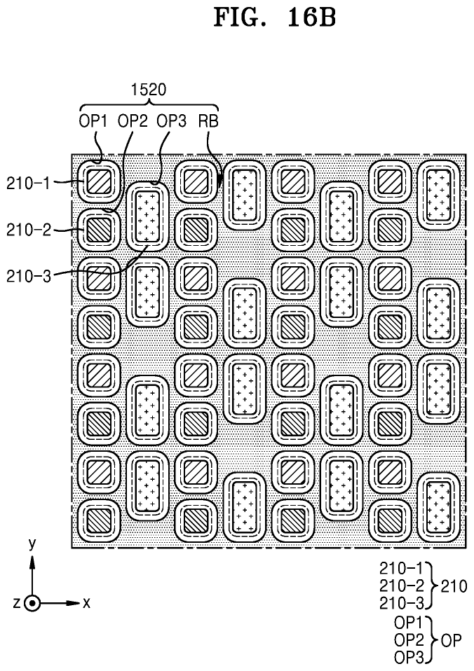

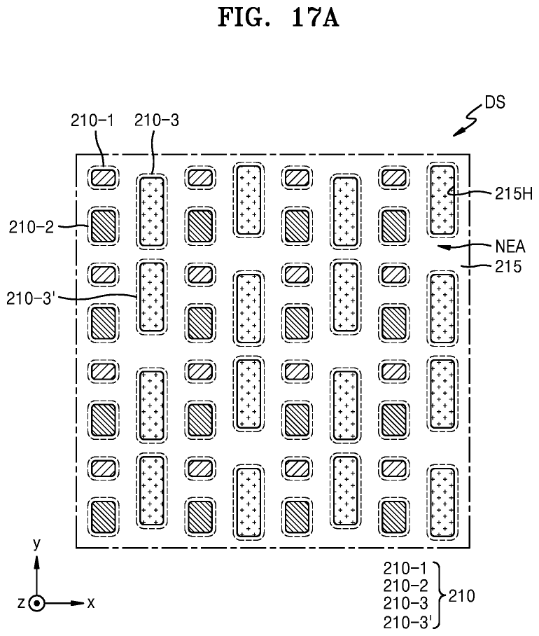

FIG. 15A is a plan view illustrating a part of a display substrate for manufacturing a display apparatus, according to an embodiment. FIG. 15B is a plan view illustrating a part of a mask sheet aligned with the display substrate of FIG. 15A, according to an embodiment. Also, FIG. 16A is a plan view illustrating a part of a display substrate for manufacturing a display apparatus, according to another embodiment. FIG. 16B is a plan view illustrating a part of a mask sheet aligned with the display substrate of FIG. 16A, according to another embodiment.

First, referring to FIGS. 15A and 16A, the display substrate DS may include a plurality of pixel electrodes 210 that are spaced apart from one another and the pixel-defining film 215 formed on the pixel electrodes 210. FIG. 15A illustrates that the plurality of pixel electrodes 210 of the display substrate DS are arranged in an RGBG type (so-called Pentile® structure). FIG. 16A illustrates that the plurality of pixel electrodes 210 are arranged in a stripe type. Such arrangements of the pixel electrodes 210 are examples, and the disclosure may be applied to various other arrangements of the pixel electrodes 210.

In an embodiment, at least two of the plurality of pixel electrodes 210 may have different sizes. For example, as shown in FIG. 15A, the plurality of pixel electrodes 210 may include the first through third pixel electrodes 210-1, 210-2, and 210-3 having different sizes. Alternatively, as shown in FIG. 16A, the first pixel electrode 210-1 and the second pixel electrode 210-2 of the plurality of pixel electrodes 210 may have the same size, and the third pixel electrode 210-3 may have a size different from that of the first pixel electrode 210-1 and the second pixel electrode 210-2.

The pixel-defining film 215 located on the pixel electrodes 210 may include the holes 215H through which the plurality of pixel electrodes 210 are respectively exposed. The holes 215H of the pixel-defining film 215 may have different sizes in a plan view according to sizes of the pixel electrodes 210 corresponding thereto.

Although not shown, the emission layers 222 emitting light may be respectively formed in the holes 215H of the pixel-defining film 215, and the counter electrode 230 may be integrally formed over the plurality of pixel electrodes 210, to form the organic light-emitting diodes OLED. Also, as described above, at least one of the first through fourth common layers 221, 223, 225, and 227 (see FIGS. 5 and 8) of the organic light-emitting diode OLED and the charge generation layer 224 (see FIG. 8) may be formed to correspond to each of the pixel electrodes 210.

Referring to FIGS. 15B and 16B, a plurality of opening portions OP may be formed in the mask sheet 1520. For example, the mask sheet 1520 may include a rib portion RB defining the plurality of opening portions OP. The opening portion OP may be formed by removing a portion of the mask sheet 1520 in a thickness direction (e.g., z-direction of FIG. 15B) of the mask sheet 1520, and the rib portion RB may be a body of the mask sheet 1520 that forms a planar shape of the opening portion OP.

The plurality of opening portions OP may be spaced apart from one another, and may have island shapes or isolated shapes in a plan view. Although each of the plurality of opening portions OP may have a substantially quadrangular shape in a plan view as shown in FIG. 15B, the inventive concepts are not limited thereto. Each opening portion OP may have a polygonal shape, such as a triangular shape or a pentagonal shape, a circular shape, an elliptical shape, or an irregular shape. In an embodiment, a shape and an arrangement of each opening portion OP may be determined according to a shape and an arrangement of the pixel electrode 210.

At least two of the plurality of opening portions OP of the mask sheet 1520 may have different sizes in a plan view. In an embodiment, as shown in FIG. 15B, the plurality of opening portions OP may include a first opening portion OP1, a second opening portion OP2, and a third opening portion OP3 having different sizes in a plan view. Alternatively, as shown in FIG. 16A, from among the plurality of opening portions OP, the first opening portion OP1 and the second opening portion OP2 may have the same size, and the third opening portion OP3 may have a size different from that of the first opening portion OP1 and the second opening portion OP2. The first through third opening portions OP1, OP2, and OP3 may respectively correspond to the first through third pixel electrodes 210-1, 210-2, and 210-3.

In a state where the mask sheet 1520 is aligned with the display substrate DS, the plurality of opening portions OP of the mask sheet 1520 may respectively overlap the plurality of pixel electrodes 210 of the display substrate DS in a plan view. The rib portion RB of the mask sheet 1520 may be located between the plurality of pixel electrodes 210 so as not to overlap the plurality of pixel electrodes 210 in a plan view. That is, all of the pixel electrodes 210 of the display substrate DS may not overlap the rib portion RB of the mask sheet 1520, and may overlap the opening portions OP of the mask sheet 1520.

A deposition material may not pass through an area covered by the rib portion RB of the mask sheet 1520, and may only pass through areas exposed by the opening portions OP of the mask sheet 1520 to be deposited on the display substrate DS. Accordingly, when the mask sheet 1520 of FIG. 15B or FIG. 16B is used, the first through fourth common layers 221, 223, 225, and 227 and the charge generation layer 224 may be formed to correspond to all of the pixel electrodes 210.

For example, when the first common layer 221 is deposited by using the mask sheet 1520, a deposition material passing through the first through third opening portions OP1, OP2, and OP3 of the mask sheet 1520 may respectively form the 1-1^{st} through 1-3^{rd} pattern units 221a, 221b, and 221c (see FIG. 6) of the first common layer 221 respectively corresponding to the first through third pixel electrodes 210-1, 210-2, and 210-3. As such, when one mask sheet 1520 is used, the first through fourth common layers 221, 223, 225, and 227 including a plurality of pattern units respectively corresponding to the first through third pixel electrodes 210-1, 210-2, and 210-3 and disconnected from one another may be formed. The same may also apply to a case where the charge generation layer 224 is formed.

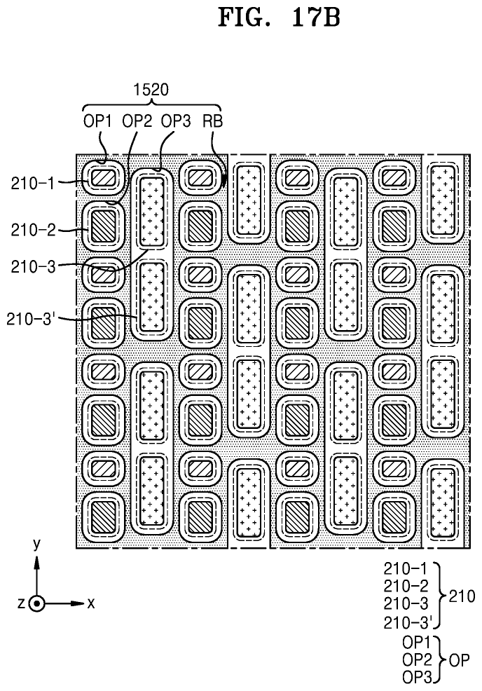

FIG. 17A is a plan view illustrating a part of a display substrate for manufacturing a display apparatus, according to another embodiment. FIG. 17B is a plan view illustrating a part of a mask sheet aligned with the display substrate of FIG. 17A, according to another embodiment. The same description as that made with reference to FIGS. 15A, 15B, 16A, and 16B will be omitted, and the following will focus on differences between FIGS. 15A, 15B, 16A, 16B and FIGS. 17A and 17B.

Referring to FIGS. 17A and 17B, the plurality of pixel electrodes 210 may include the first through third pixel electrodes 210-1, 210-2, and 210-3 located in a stripe type and having different sizes.

In an embodiment, at least one of the plurality of opening portions OP of the mask sheet 1520 may overlap two pixel electrodes 210 that are adjacent to each other and have the same size from among the plurality of pixel electrodes 210. For example, one third opening portion OP3 of the mask sheet 1520 may overlap two third pixel electrodes 210-3 and 210-3′ that are adjacent to each other and have the same size in a plan view.

Two organic light-emitting diodes respectively including the two third pixel electrodes 210-3 and 210-3′ in the completed display apparatus 1 (see FIG. 1) may emit light of the same color. Accordingly, display quality degradation due to leakage current between the two organic light-emitting diodes may be prevented. In this regard, the plurality of opening portions OP of the mask sheet 1520 may be formed to have more various patterns.

According to the one or more embodiments, a display apparatus for improving display quality by preventing undesirable light emission due to leakage current, a mask assembly for manufacturing the display apparatus, and an apparatus of manufacturing the display apparatus may be implemented. Also, as design restrictions on a common layer that is a main path of leakage current are overcome, a display apparatus for improving the lifetime and luminous efficiency of an organic light-emitting diode, a mask assembly for manufacturing the display apparatus, and an apparatus for manufacturing the display apparatus may be implemented. However, the inventive concepts are not limited by these effects.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display apparatus comprising:
a substrate;
a first pixel electrode, a second pixel electrode, and a third pixel electrode disposed on the substrate and arranged adjacent to one another;
a first lower emission layer, a second lower emission layer, and a third lower emission layer respectively corresponding to the first through third pixel electrodes and configured to emit light of different wavelength bands;
a counter electrode disposed on the first through third lower emission layers; and
a first common layer located between the first through third pixel electrodes and the first through third lower emission layers,
tt wherein the first common layer comprises a 1-1^{st} pattern unit, a 1-2^{nd} pattern unit, and a 1-3^{rd} pattern unit respectively corresponding to the first through third pixel electrodes and disconnected from one another.

2. The display apparatus of claim 1, further comprising a second common layer located between the first through third lower emission layers and the counter electrode,
wherein the second common layer comprises a 2-1^{st} pattern unit, a 2-2^{nd} pattern unit, and a 2-3^{rd} pattern unit respectively corresponding to the first through third pixel electrodes and disconnected from one another.

3. The display apparatus of claim 2, further comprising:
a first upper emission layer disposed on the first lower emission layer, arranged to overlap the first lower emission layer, and configured to emit light of a same wavelength band as that of the first lower emission layer;
a second upper emission layer disposed on the second lower emission layer, arranged to overlap the second lower emission layer, and configured to emit light of a same wavelength band as that of the second lower emission layer; and
a third upper emission layer disposed on the third lower emission layer, arranged to overlap the third lower emission layer, and configured to emit light of a same wavelength band as that of the third lower emission layer,
wherein the first through third upper emission layers are located under the counter electrode with the second common layer therebetween.

4. The display apparatus of claim 3, wherein:
thicknesses of the first through third upper emission layers are different from one another; and
thicknesses of the first through third lower emission layers are different from one another.

5. The display apparatus of claim 3, further comprising a charge generation layer located between the first through third lower emission layers and the first through third upper emission layers.

6. The display apparatus of claim 5, wherein:
the charge generation layer comprises an n-type charge generation layer and a p-type charge generation layer; and
at least one of the n-type charge generation layer and the p-type charge generation layer comprises a first portion, a second portion, and a third portion respectively corresponding to the first through third lower emission layers and disconnected from one another.

7. The display apparatus of claim 5, further comprising a third common layer located between the first through third lower emission layers and the charge generation layer,
wherein the third common layer comprises a 3-1^{st} pattern unit, a 3-2^{nd} pattern unit, and a 3-3^{rd} pattern unit respectively corresponding to the first through third pixel electrodes and disconnected from one another.

8. The display apparatus of claim 5, further comprising a fourth common layer located between the charge generation layer and the first through third upper emission layers,
wherein the fourth common layer comprises a 4-1^{st} pattern unit, a 4-2^{nd} pattern unit, and a 4-3^{rd} pattern unit respectively corresponding to the first through third pixel electrodes and disconnected from one another.

9. A display apparatus comprising:
a substrate;
a first pixel electrode, a second pixel electrode, and a third pixel electrode disposed on the substrate and arranged adjacent to one another;
a first lower emission layer, a second lower emission layer, and a third lower emission layer respectively corresponding to the first through third pixel electrodes and configured to emit light of different wavelength bands;
a first upper emission layer disposed on the first lower emission layer, arranged to overlap the first lower emission layer, and configured to emit light of a same wavelength band as that of the first lower emission layer;
a second upper emission layer disposed on the second lower emission layer, arranged to overlap the second lower emission layer, and configured to emit light of a same wavelength band as that of the second lower emission layer;
a third upper emission layer disposed on the third lower emission layer, arranged to overlap the third lower emission layer, and configured to emit light of a same wavelength band as that of the third lower emission layer;
a charge generation layer located between the first lower emission layer and the first upper emission layer, between the second lower emission layer and the second upper emission layer, and between the third lower emission layer and the third upper emission layer; and
a counter electrode located on the first through third upper emission layers,
wherein the charge generation layer comprises a first portion, a second portion, and a third portion respectively corresponding to the first through third lower emission layers and disconnected from one another.

10. The display apparatus of claim 9, further comprising a first common layer located between the first through third pixel electrodes and the first through third lower emission layers,
wherein the first common layer comprises a 1-1^{st} pattern unit, a 1-2^{nd} pattern unit, and a 1-3^{rd} pattern unit respectively corresponding to the first through third pixel electrodes and disconnected from one another.

11. The display apparatus of claim 9, further comprising a second common layer located between the first through third lower emission layers and the counter electrode,
wherein the second common layer comprises a 2-1^{st} pattern unit, a 2-2^{nd} pattern unit, and a 2-3^{rd} pattern unit respectively corresponding to the first through third pixel electrodes and disconnected from one another.

12. The display apparatus of claim 9, further comprising a third common layer located between the first through third lower emission layers and the charge generation layer,
wherein the third common layer comprises a 3-1^{st} pattern unit, a 3-2^{nd} pattern unit, and a 3-3^{rd} pattern unit respectively corresponding to the first through third pixel electrodes and disconnected from one another.

13. The display apparatus of claim 9, further comprising a fourth common layer located between the charge generation layer and the first through third upper emission layers,
wherein the fourth common layer comprises a 4-1^{st} pattern unit, a 4-2^{nd} pattern unit, and a 4-3^{rd} pattern unit respectively corresponding to the first through third pixel electrodes and disconnected from one another.

14. The display apparatus of claim 9, wherein:
thicknesses of the first through third upper emission layers are different from one another; and
thicknesses of the first through third lower emission layers are different from one another.

15. A mask assembly comprising:
a mask frame; and
a mask sheet located on the mask frame and comprising a rib portion defining a plurality of opening portions,
wherein at least two of the plurality of opening portions of the mask sheet have different sizes in a plan view.

16. The mask assembly of claim 15, wherein the rib portion of the mask sheet defines a first opening portion, a second opening portion, and a third opening portion having different sizes in a plan view.

17. An apparatus for manufacturing a display apparatus, the apparatus comprising:
a mask assembly aligned with a display substrate; and
a deposition source located opposite to the display substrate with the mask assembly therebetween,
wherein:
the mask assembly comprises:
a mask frame; and
a mask sheet located on the mask frame and comprising a rib portion defining a plurality of opening portions; and
at least two of the plurality of opening portions of the mask sheet have different sizes in a plan view.

18. The apparatus of claim 17, wherein the rib portion of the mask sheet defines a first opening portion, a second opening portion, and a third opening portion having different sizes in a plan view.

19. The apparatus of claim 17, wherein:
the display substrate comprises a plurality of pixel electrodes that are spaced apart from one another; and
the rib portion of the mask sheet is located between the plurality of pixel electrodes without overlapping the plurality of pixel electrodes in a plan view.

20. The apparatus of claim 19, wherein at least one of the plurality of opening portions of the mask sheet overlaps two pixel electrodes that are adjacent to each other and have a same size from among the plurality of pixel electrodes.
